(19) United States
(12) Patent Application Publication
(10) Pub. No.: US 2020/0264959 A1
(43) Pub. Date: Aug. 20, 2020

(54) STORAGE DEVICE AND METHOD OF OPERATING THE SAME

(71) Applicant: SK hynix Inc., Gyeonggi-do (KR)

(72) Inventor: Eu Joon BYUN, Gyeonggi-do (KR)

(21) Appl. No.: 16/589,900

(22) Filed: Oct. 1, 2019

(30) Foreign Application Priority Data
Feb. 15, 2019 (KR) 10-2019-0017946

(51) Int. Cl. G06F 11/14; G06F 11/30; G06F 12/02; G06F 13/16; G11C 11/4072; G11C 11/4074; G06F 1/28

(52) U.S. Cl. CPC G06F 11/1471; G06F 11/3037; G06F 12/0246; G06F 1/28; G11C 11/4072; G11C 11/4074; G06F 13/1689

(57) ABSTRACT

Provided herein may be a memory controller configured to control a memory device. The memory controller may include: a sudden power off (SPO) sensing unit configured to sense an SPO event and generate sensing information based on the SPO event, an SPO level determination unit configured to determine an SPO level based on the sensing information, a system data control unit configured to determine system data to be written based on the SPO level, and a write time point at which the system data is written, and generate a command for storing the system data at the determined write time point, and a system data storage configured to store the system data. The system data storage may include a nonvolatile memory.

### CROSS-REFERENCE TO RELATED APPLICATION

The present application claims priority under 35 U.S.C. § 119(a) to Korean patent application number 10-2019-0017946 filed on Feb. 15, 2019, the entire disclosure of which is herein incorporated by reference in its entirety.

### BACKGROUND

### Field of Invention

Various embodiments of the present disclosure generally relate to an electronic device, and more particularly, to a storage device and a method of operating the storage device.

### Description of Related Art

Generally, a storage device stores data under control of a host device such as a computer, a smartphone, or a smartpad. Examples of the storage device may be classified into a device such as a hard disk drive (HDD) which stores data in a magnetic disk, and a device such as a solid state drive (SSD) or a memory card which stores data in a semiconductor memory, particularly, a nonvolatile memory.

A storage device may include a memory device in which data is stored, and a memory controller configured to store data in the memory device. Memory devices may be classified into volatile memories and nonvolatile memories. Representative examples of the nonvolatile memories may include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), and a ferroelectric RAM (FRAM).

### SUMMARY

Various embodiments of the present disclosure are directed to a storage device capable of changing a system data write period, and a method of operating the storage device.

An embodiment of the present disclosure may provide for a memory controller configured to control a memory device, the memory controller including: a sudden power off (SPO) sensing unit configured to sense an SPO event and generate sensing information based on the SPO event, an SPO level determination unit configured to determine an SPO level based on the sensing information, a system data control unit configured to determine system data to be written based on the SPO level, and a write time point at which the system data is written, and generate a command for storing the system data at the determined write time point and a system data storage configured to store the system data, wherein the system data storage includes a nonvolatile memory.

An embodiment of the present disclosure may provide for a method of operating a memory controller configured to control a memory device, the method including: sensing a sudden power off (SPO) event and generating sensing information based on the SPO event, determining an SPO level based on the sensing information, determining system data to be written and a write time point at which the system data is written, based on the SPO level, and generating a command for storing the system data at the determined write time point.

An embodiment of the present disclosure may provide for a storage device including: a memory device configured to store data, a memory controller configured to sense a sudden power off (SPO) event and determine an SPO level, and determine system data to be written based on the SPO level, and a write time point at which the system data is written and a system data storage configured to store the system data, wherein the system data storage includes a nonvolatile memory.

An embodiment of the present disclosure may provide for a storage device including: a memory device configured to store data and a controller configured to detect occurrences of a sudden power off (SPO), determine a write period based on the occurrences of SPO, and store system data in the memory device at the determined write period, wherein the write period is variably adjusted based on the occurrences of SPO.

### BRIEF DESCRIPTION OF THE DRAWINGS

FIG. 1. is a block diagram illustrating a storage device in accordance with an embodiment of the present disclosure.

FIG. 2 is a diagram illustrating a memory controller in accordance with an embodiment of the present disclosure.

FIG. 3 is a diagram illustrating a memory controller including a sudden power off (SPO) record unit in accordance with an embodiment of the present disclosure.

FIG. 4 is a diagram illustrating an operation of updating a sudden power off (SPO) occurrence count number in accordance with an embodiment of the present disclosure.

FIG. 5 is a diagram illustrating a method of updating a sudden power off (SPO) occurrence period and the SPO occurrence count number in accordance with an embodiment of the present disclosure.

FIG. 6 is a diagram illustrating system data in accordance with an embodiment of the present disclosure.

FIG. 7 is a diagram illustrating a method of determining a sudden power off (SPO) level in accordance with an embodiment of the present disclosure.

FIG. 8 is a diagram illustrating a method of determining a sudden power off (SPO) level in accordance with an embodiment of the present disclosure.

FIG. 9 is a block diagram illustrating a memory device in accordance with an embodiment of the present disclosure.

FIG. 10 is a diagram illustrating a memory cell array in accordance with an embodiment of the present disclosure.

FIG. 11 is a circuit diagram illustrating a memory block in accordance with an embodiment of the present disclosure.

FIG. 12 is a circuit diagram illustrating a memory block in accordance with an embodiment of the present disclosure.

FIG. 13 is a diagram illustrating an operation of a memory controller in accordance with an embodiment of the present disclosure.

FIG. 14 is a diagram illustrating an operation of a memory controller in accordance with an embodiment of the present disclosure.

FIG. 15 is a diagram illustrating an operation of a memory device in accordance with an embodiment of the present disclosure.

FIG. 16 is a diagram illustrating an operation of a memory controller in accordance with an embodiment of the present disclosure.

FIG. 17 is a diagram illustrating an operation of a memory controller in accordance with an embodiment of the present disclosure.

FIG. 18 is a diagram illustrating a memory controller in accordance with an embodiment of the present disclosure.

FIG. 19 is a block diagram illustrating a memory card system including a storage device in accordance with an embodiment of the present disclosure.

FIG. 20 is a block diagram illustrating a solid state drive (SSD) system including a storage device in accordance with an embodiment of the present disclosure.

FIG. 21 is a block diagram illustrating a user system including a storage device in accordance with an embodiment of the present disclosure.

### DETAILED DESCRIPTION

Specific structural or functional descriptions in the embodiments of the present disclosure introduced in this specification or application are only for description of the embodiments of the present disclosure. The descriptions should not be construed as being limited to the embodiments described in the specification or application.

The present disclosure will now be described in detail based on embodiments. The present disclosure may, however, be embodied in many different forms and should not be construed as being limited to only the embodiments set forth herein, but should be construed as covering modifications, equivalents or alternatives falling within ideas and technical scopes of the present disclosure. However, it is to be understood that the present description is not intended to limit the present disclosure to those exemplary embodiments, and the present disclosure is intended to cover not only the exemplary embodiments, but also various alternatives, modifications, equivalents and other embodiments that fall within the spirit and scope of the present disclosure.

It will be understood that, although the terms “first”, “second”, etc. may be used herein to describe various elements, these elements should not be limited by these terms. These terms are only used to distinguish one element, from another element. For instance, a first element discussed below could be termed a second element without departing from the teachings of the present disclosure. Similarly, the second element could also be termed the first element.

It will be understood that when an element is referred to as being “coupled” or “connected” to another element, it can be directly coupled or connected to the other element or intervening elements may be present therebetween. In contrast, it should be understood that when an element is referred to as being “directly coupled” or “directly connected” to another element, there are no intervening elements present. Other expressions that describe the relationship between elements, such as “between”, “directly between”, “adjacent to” or “directly adjacent to” should be construed in the same way.

The terminology used herein is for the purpose of describing particular embodiments only and is not intended to be limiting. In the present disclosure, the singular forms are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which the present disclosure belongs. It will be further understood that terms used herein should be interpreted as having a meaning that is consistent with their meaning in the context of this specification and the relevant art, and will not be interpreted in an idealized or overly formal sense unless expressly so defined herein.

Detailed description of functions and structures well known to those skilled in the art will be omitted to avoid obscuring the subject matter of the present disclosure. This aims to omit unnecessary description so as to make the subject matter of the present disclosure clear.

Various embodiments of the present disclosure will now be described more fully hereinafter with reference to the accompanying drawings, in which preferred embodiments of the present disclosure are shown, so that those of ordinary skill in the art can easily carry out the technical idea of the present disclosure.

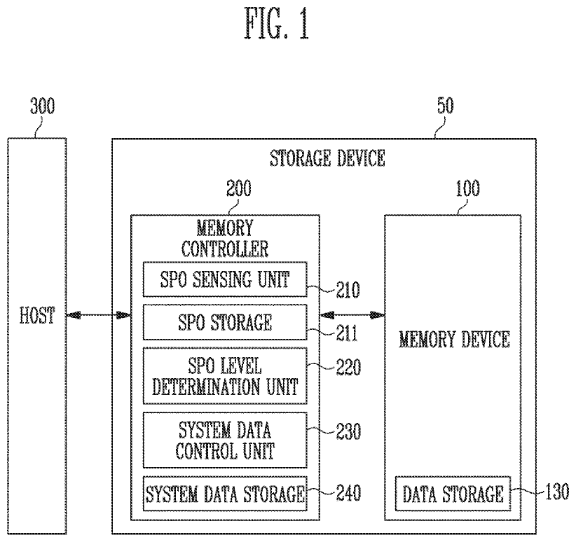

FIG. 1 is a block diagram illustrating a storage device 50 in accordance with an embodiment of the present disclosure.

Referring to FIG. 1, the storage device 50 may include a memory device 100 and a memory controller 200.

The storage device 50 may be a device configured to store data under control of a host 300 such as a cellular phone, a smartphone, an MP3 player, a laptop computer, a desktop computer, a game machine, a television (TV), a tablet personal computer (PC), or an in-vehicle infotainment system.

The storage device 50 may be manufactured as any one of various kinds of storage devices depending on a host interface, which is a communication system with the host 300. For example, the data storage device 50 may be configured of any one of various types of storage devices such as an SSD, MMC, eMMC, RS-MMC, or micro-MMC type multimedia card, an SD, mini-SD, micro-SD type secure digital card, a universal serial bus (USB) storage device, a universal flash storage (UFS) device, a personal computer memory card international association (PCMCIA) card type storage device, a peripheral component interconnection (PCI) card type storage device, a PCI-express (PCI-e or PCIe) type storage device, a compact flash (CF) card, a smart media card, and a memory stick.

The storage device 50 may be manufactured in the form of any one of various package types. For instance, the storage device 50 may be manufactured in the form of any one of various package types such as a package on package (POP) type, a system in package (SIP) type, a system on chip (SOC) type, a multi-chip package (MCP) type, a chip on board (COB) type, a wafer-level fabricated package (WFP) type, and a wafer-level stack package (WSP) type.

The memory controller 200 may control overall operations of the storage device 50.

When power is applied to the storage device 50, the memory controller 200 may execute firmware. In the case where the memory device 100 is a flash memory device, the memory controller 200 may execute firmware such as a flash translation layer (FTL) for controlling communication between the host 300 and the memory device 100.

The memory controller 200 may include a sudden power off (SPO) sensing unit 210. The SPO sensing unit 210 may sense an SPO event. The SPO event may be a phenomenon in which the power is suddenly turned off. If the power is suddenly turned off, the SPO sensing unit 210 may control the memory device 100 to store a point in time at which the power is turned off. The point in time at which the power is turned off may be a power off time PO_TIME. The power off time PO_TIME may be stored in the memory device 100 and/or the memory controller 200.

If the power is turned on again after the power off, the SPO sensing unit 210 may receive the power off time PO _TIME from the memory device 100. Therefore, the SPO sensing unit 210 may calculate an SPO duration, based on a duration from the point in time at which the power is turned off to the point in time at which the power is turned on.

The SPO sensing unit 210 may sense an SPO event and generate sensing information SE_INF. In various embodiments, the SPO sensing unit 210 may generate the sensing information SE_INF, based on the SPO duration. The sensing information SE_INF may include at least one of the number of times the SPO event has occurred for a reference time t_ref, and an SPO occurrence period SPO_PER. The SPO occurrence period SPO_PER may be an average of SPO durations.

The memory controller 200 may include an SPO storage 211. The SPO storage 211 may store a power off time PO_TIME sensed by the SPO sensing unit 210. Furthermore, the SPO storage 211 may store an SPO occurrence time which is a time between stored power off times PO_TIME.

In an embodiment, the SPO storage 211 may be formed of a nonvolatile memory. Therefore, the power off time PO_TIME and the SPO occurrence time that are stored in the SPO storage 211 may be retained in the SPO storage 211 even if the power is turned off. Even if the power is turned off, the power off time PO_TIME and the SPO occurrence time may be stored in the SPO storage 211.

The memory controller 200 may include an SPO level determination unit 220. The SPO level determination unit 220 may receive the sensing information SE_INF from the SPO sensing unit 210. The SPO level determination unit 220 may determine an SPO level SPO_LEVEL based on the sensing information SE_INF. Depending on the SPO level SPO_LEVEL, system data SYS_DATA to be written and a point in time (i.e., a write time point) at which the system data SYS_DATA is written may be determined.

In an embodiment, as an SPO occurrence count number SPO_NUM is increased, the SPO level SPO_LEVEL may be increased. The SPO occurrence count number SPO_NUM may be the number of times the SPO event has occurred for the reference time t_ref. In contrast, as the SPO occurrence count number SPO_NUM is decreased, the SPO level SPO_LEVEL may be reduced.

In an embodiment, as the SPO occurrence period SPO_PER is decreased, the SPO level SPO_LEVEL may be increased. In contrast, as the SPO occurrence period SPO_PER is increased, the SPO level SPO_LEVEL may be decreased.

Based on the SPO level SPO_LEVEL, the type of system data SYS_DATA to be stored in the memory controller 200 and/or the memory device 100 may be determined. An area of the memory controller 200 or the memory device 100 in which the system data SYS_DATA is to be stored may include nonvolatile memory cells or nonvolatile memory.

Furthermore, based on the SPO level SPO_LEVEL, a period and/or count number of writing the system data SYS_DATA in the nonvolatile memory cells may be determined. The system data SYS_DATA may include at least one of host related data HOST_DATA, user related data USER_DATA, firmware related data FW_DATA, and mapping related data MAP_DATA.

The memory controller 200 may include a system data control unit 230. The system data control unit 230 may receive the SPO level SPO_LEVEL from the SPO level determination unit 220.

The system data control unit 230 may determine, based on the SPO level SPO_LEVEL, the type of system data SYS_DATA to be written. In various embodiments, as the SPO level SPO_LEVEL is increased, the number of types of system data SYS_DATA to be written may be increased. In contrast, as the SPO level SPO_LEVEL is decreased, the number of types of system data SYS_DATA to be written may be decreased.

The system data control unit 230 may determine, based on the SPO level SPO_LEVEL, a write time point at which system data SYS_DATA is written. In various embodiments, as the SPO level SPO_LEVEL is increased, the number of times system data SYS_DATA is written to the nonvolatile memory cells of the memory controller 200 or the memory device 100 may be increased, and the time between write time points may be decreased. In various embodiments, as the SPO level SPO_LEVEL is decreased, the number of times system data SYS_DATA is written to the nonvolatile memory cells may be decreased, and the time between write time points may be increased.

The system data control unit 230 may write system data SYS_DATA in the memory device 100 and/or the memory controller 200 based on the SPO level SPO_LEVEL. An area to which the system data SYS_DATA is to be written may include nonvolatile memory cells.

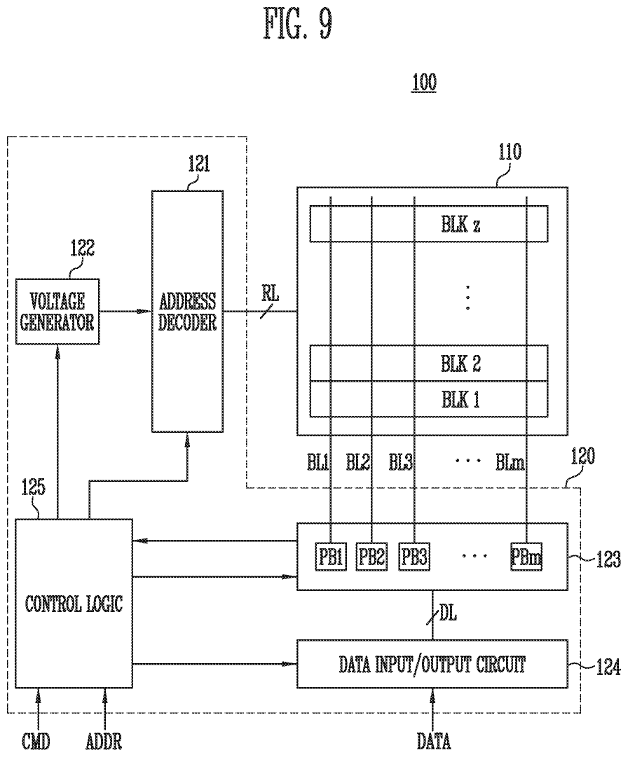

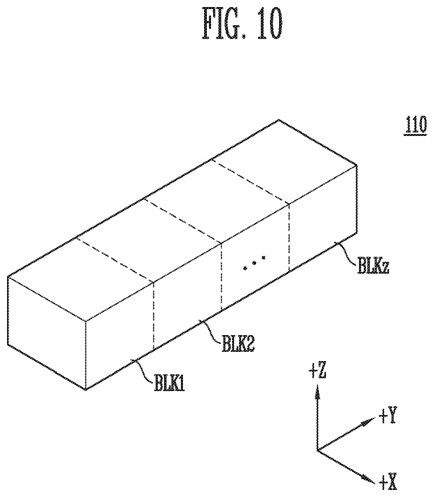

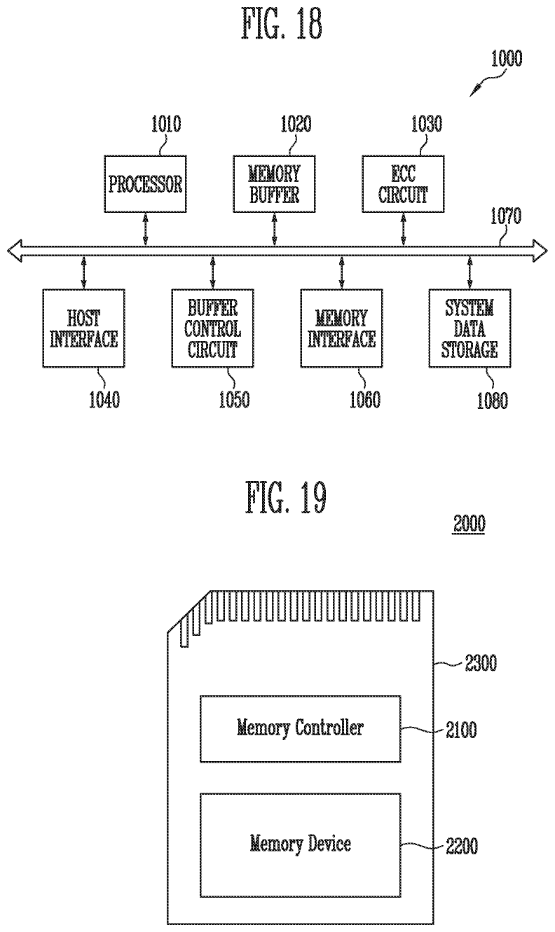

The system data control unit 230 may write the system data SYS_DATA in the nonvolatile memory cells at a write time point determined based on the SPO level SPO_LEVEL. In an embodiment, the system data control unit 230 may write system data SYS_DATA in the system data storage 240. In an embodiment, the system data control unit 230 may write system data SYS_DATA in a data storage 130 of the memory device 100. In various embodiments, the memory device 100 may receive the system data SYS_DATA from the system data control unit 230 through an interface of the memory controller 200 (e.g., a memory interface 1060 of FIG. 18) and a peripheral circuit (e.g., a data input/output circuit 124 of FIG. 9) of the memory device 100, and store the received system data SYS_DATA in the data storage 130.

The system data control unit 230 may write the system data SYS_DATA when system data write conditions are satisfied. In various embodiments, the system data SYS_DATA may be written when a memory block in which data is stored is changed in the memory device 100. Therefore, the system data SYS_DATA may be written when mapping data is updated. Furthermore, the system data SYS_DATA may be written when mapping information (e.g., physical-to-logical (P2L) mapping information) indicating a mapping relationship between physical block addresses (PBAs) and logical block addresses (LBAs) is updated.

Consequently, if the system data write conditions are satisfied, the system data control unit 230 may write the system data SYS_DATA determined based on the SPO level SPO_LEVEL at a write time point determined based on the SPO level SPO_LEVEL.

The system data control unit 230 may store the system data SYS_DATA to cope with an SPO event in which the power is turned off at an unspecified point in time. If the system data SYS_DATA is frequently stored in the nonvolatile memory, the amount of changed system data may be decreased. Therefore, since the amount of system data SYS_DATA to be recovered is decreased, a recovery time is decreased so that the time it takes to perform booting may be decreased. However, if the system data SYS_DATA is frequently stored in the nonvolatile memory, the performance of the storage device 50 may be decreased. The operational efficiency of the storage device 50 may be decreased. Hence, the system data control unit 230 may determine an optimal write time point for the system data SYS_DATA and the type of system data SYS_DATA to be stored, so as to cope with an SPO event.

In an embodiment, the memory controller 200 may include a system data storage 240. In an embodiment, the memory controller 200 may not include the system data storage 240.

In the case where the memory controller 200 includes the system data storage 240, the system data storage 240 may include volatile memory cells or nonvolatile memory cells. If the system data storage 240 includes nonvolatile memory cells, the system data storage 240 may include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), a spin-transfer torque magnetoresistive RAM (STT-MRAM), or a phase-change RAM (PCRAM).

In the case where the system data storage 240 includes a nonvolatile memory or nonvolatile memory cells, the system data control unit 230 may store the system data SYS DATA in the system data storage 240. Since the system data storage 240 includes nonvolatile memory cells, the system data SYS_DATA stored in the system data storage 240 may be retained even if the power is turned off. Therefore, if the power is turned on again after the power off, the storage device 50 including the memory controller 200 and the memory device 100 may perform a recovery operation based on the system data SYS_DATA stored in the system data storage 240.

In an embodiment, the system data storage 240 may be disposed outside the memory controller 200. The system data storage 240 may be included in the storage device 50 as a component separately provided from the memory controller 200.

In an embodiment, the system data storage 240 may be included in the memory device 100.

The memory device 100 may store data therein. The memory device 100 may operate under control of the memory controller 200. The memory device 100 may include a memory cell array including a plurality of memory cells configured to store data therein. The memory cell array may include a plurality of memory blocks. Each memory block may include a plurality of memory cells. Each memory block may include a plurality of pages. In an embodiment, each page may be the unit for storing data in the memory device 100 or reading stored data from the memory device 100. Each memory block may be the unit of erasing data.

In an embodiment, the memory device 100 may be a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), a NAND flash memory, a vertical NAND flash memory, a NOR flash memory device, a resistive random access memory (RRAM), a phase-change memory (PRAM), a magnetoresistive random access memory (MRAM), a ferroelectric random access memory (FRAM), or a spin transfer torque random access memory (STT-RAM). In this specification, the memory device 100 is a NAND flash memory.

In an embodiment, the memory device 100 may be embodied in a three-dimensional array structure. The present disclosure may be applied not only to a flash memory in which a charge storage layer is formed of a conductive floating gate (FG), but also to a charge trap flash (CTF) memory in which a charge storage layer is formed of an insulating layer.

In an embodiment, each of the memory cells included in the memory device 100 may be formed of a single-level cell (SLC) capable of storing one bit of data. Alternatively, each of the memory cells included in the memory device 100 may be formed of a multi-level cell (MLC) capable of storing two bits of data, a triple-level cell (TLC) capable of storing three bits of data, or a quad-level cell (QLC) capable of storing four bits of data.

The memory device 100 may receive a command and an address from the memory controller 200 and access an area of the memory cell array that is selected by the address. The memory device 100 may perform an operation corresponding to the command on the region selected by the address. For example, the memory device 100 may perform a write (or program) operation, a read operation, and an erase operation. During a program operation, the memory device 100 may program data to an area selected by an address. During a read operation, the memory device 100 may read data from an area selected by an address. During an erase operation, the memory device 100 may erase data from an area selected by an address.

The memory device 100 may perform a program operation or an erase operation using a set operating voltage under control of the memory controller 200.

The memory device 100 may include a data storage 130. In an embodiment, the data storage 130 may store system data SYS_DATA received from the system data control unit 230. In various embodiments, the data storage 130 may receive the system data SYS_DATA from the system data control unit 230 through a peripheral circuit (e.g., a data input/output circuit 124 of FIG. 9) of the memory device 100 and an interface of the memory controller 200 (e.g., a memory interface 1060 of FIG. 18). However, it is noted that descriptions will be made such that the data storage 130 may store system data SYS_DATA received from the system data control unit 230. The data storage 130 may include nonvolatile memory cells. The data storage 130 may receive a command from the system data control unit 230 so as to store the system data SYS_DATA. The data storage 130 may store the system data SYS_DATA based on the command received from the system data control unit 230. The data storage 130 may have the same function as that of the system data storage 240.

Therefore, if the power is turned on again after the power is turned off, the system data SYS_DATA stored in the data storage 130 may be provided to the memory controller 200. The memory controller 200 may receive the system data SYS_DATA and perform a recovery operation.

In an embodiment, the memory controller 200 may receive data and a logical block address (LBA) from the host 300, and translate the LBA into a physical block address (PBA) indicating addresses of memory cells in which data is stored, the memory cells being included in the memory device 100. In addition, the memory controller 200 may store, in a buffer memory, mapping information indicating a mapping relationship between the LBAs and the PBAs.

The memory controller 200 may control the memory device 100 to perform a program operation, a read operation, or an erase operation in response to a request from the host 300. During a program operation, the memory controller 200 may provide a program command, a PBA, and data to the memory device 100. During a read operation, the memory controller 200 may provide a read command and a PBA to the memory device 100. During an erase operation, the memory controller 200 may provide an erase command and a PBA to the memory device 100.

In an embodiment, the memory controller 200 may autonomously generate a program command, an address and data without a request from the host 300, and transmit them to the memory device 100. For example, the memory controller 200 may provide a command, an address and data to the memory device 100 to perform background operations such as a program operation for wear leveling, and a program operation for garbage collection.

In an embodiment, the memory controller 200 may control at least two or more memory devices 100. In this case, the memory controller 200 may control the memory devices 100 in an interleaving manner so as to enhance the operating performance.

The host 300 may communicate with the storage device 50 using at least one of various communication methods such as universal serial bus (USB), serial AT attachment (SATA), serial attached SCSI (SAS), high speed interchip (HSIC), small computer system interface (SCSI), peripheral component interconnection (PCI), PCI express (PCIe), nonvolatile memory express (NVMe), universal flash storage (UFS), secure digital (SD), multimedia card (MMC), embedded MMC (eMMC), dual in-line memory module (DIMM), registered DIMM (RDIMM), and load reduced DIMM (LRDIMM) communication methods.

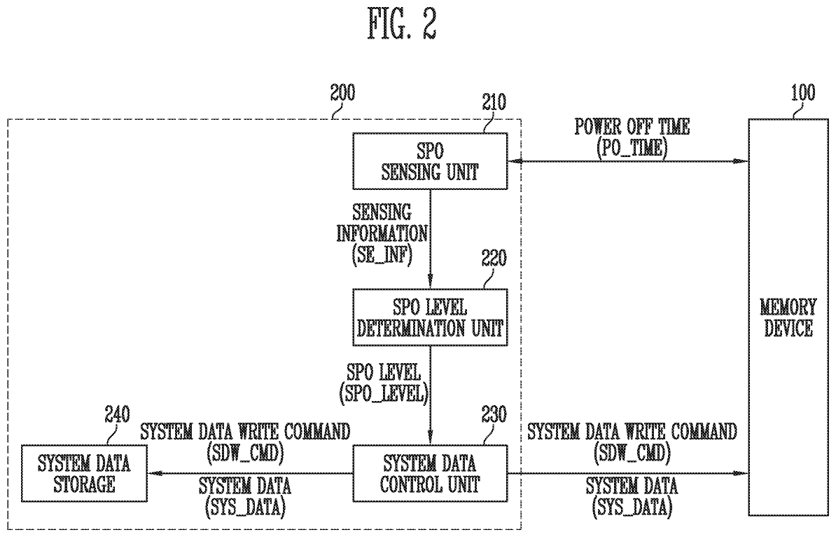

FIG. 2 is a diagram illustrating a memory controller in accordance with an embodiment of the present disclosure, for example, the memory controller 200 of FIG. 1.

Referring to FIG. 2, the memory controller 200 may include the SPO sensing unit 210, the SPO level determination unit 220, the system data control unit 230, and the system data storage 240. In an embodiment, the memory controller 200 may not include the system data storage 240. In FIG. 2, the SPO storage 211 among the components of the memory controller 200 is omitted.

The SPO sensing unit 210 may sense an SPO event. The SPO event may be a phenomenon in which the power is suddenly turned off. The SPO sensing unit 210 may sense an SPO event and store a point in time at which the SPO event is sensed in the memory device 100. In various embodiments, if the power is suddenly turned off, i.e., if an SPO event occurs, the SPO sensing unit 210 may be controlled such that a point in time at which the power is turned off is stored in the memory device 100. The point in time at which the power is turned off may be a power off time PO_TIME. The power off time PO_TIME may be stored in the memory device 100 and/or the memory controller 200. In this drawing, the power off time PO_TIME is stored in the memory device 100. Hence, when the power is turned off, the SPO sensing unit 210 may store the power off time PO_TIME in the memory device 100.

The SPO sensing unit 210 may receive the power off time PO_TIME from the memory device 100. In various embodiments, if the power is turned on again after the SPO event, the SPO sensing unit 210 may receive the power off time PO_TIME from the memory device 100. When the power is turned on, the SPO sensing unit 210 may receive the power off time PO_TIME and generate sensing information SE_INF. The sensing information SE_INF may include information about the number of times the SPO event has occurred for the reference time t_ref. Furthermore, the sensing information SE_INF may include information about an SPO occurrence period.

Therefore, the SPO sensing unit 210 may generate the sensing information SE_INF based on a duration from the point in time at which the power is turned off to the point in time at which the power is turned on. The sensing information SE_INF may be generated based on an average of durations during which power-off states due to SPO events are maintained.

The SPO level determination unit 220 may determinate an SPO level SPO_LEVEL. In various embodiments, the SPO level determination unit 220 may determinate the SPO level SPO_LEVEL based on the sensing information SE_INF received from the SPO sensing unit 210. The SPO level SPO_LEVEL may be determined based on information about the number of times the SPO event has occurred for the reference time t_ref. Alternatively, the SPO level SPO_LEVEL may be determined depending on the SPO occurrence period. The SPO occurrence period may be an average of power-off durations of SPO events that have occurred a reference number of times.

In an embodiment, the sensing information SE_INF may include the information about the number of times the SPO event has occurred for the reference time t_ref. Here, as the number of times the SPO event has occurred is increased, the SPO level SPO_LEVEL may be increased. In contrast, as the number of times the SPO event has occurred is decreased, the SPO level SPO_LEVEL may be decreased.

In an embodiment, the sensing information SE_INF includes information about an SPO occurrence period. Here, as the SPO occurrence period is decreased, the SPO level SPO_LEVEL may be increased. In contrast, as the SPO occurrence period is increased, the SPO level SPO_LEVEL may be decreased.

Consequently, the higher the SPO level SPO_LEVEL, the more frequently the SPO event occurs. In contrast, if the SPO level SPO_LEVEL is sufficiently decreased, the SPO event may seldom occur. Therefore, as the SPO level SPO_LEVEL is increased, the time between write time points at which the system data SYS_DATA is written is decreased. As the SPO level SPO_LEVEL is decreased, the time between write time points at which the system data SYS_DATA is written is increased.

Based on the SPO level SPO_LEVEL, the type and the write count number of system data SYS_DATA to be stored in the memory controller 200 and/or the memory device 100 may be determined. The system data SYS_DATA may include at least one of host related data HOST_DATA, user related data USER-_DATA, firmware related data FW_ DATA, and mapping related data MAP_DATA.

In various embodiments, as the SPO level SPO_LEVEL is increased, the number of times the system data SYS_DATA is written may be increased. As the SPO level SPO_LEVEL is increased, the time between write time points at which the system data SYS_DATA is written may be decreased. In contrast, as the SPO level SPO_LEVEL is decreased, the number of times the system data SYS_DATA is written may be decreased. As the SPO level SPO_LEVEL is decreased, the time between write time points at which the system data SYS_DATA is written may be increased.

Consequently, as the SPO level SPO_LEVEL is decreased, the number of times the system data SYS_DATA is written is decreased, so that the efficiency of the storage device may be increased. The performance of the storage device may be enhanced by adjusting the number of times the system data SYS_DATA is written. In contrast, as the SPO level SPO_LEVEL is increased, the number of times the system data SYS_DATA is written is increased. In this case, the amount of system data SYS_DATA to be recovered by the storage device may be decreased by frequently writing the system data SYS_DATA. Thereby, the performance of the storage device may be enhanced.

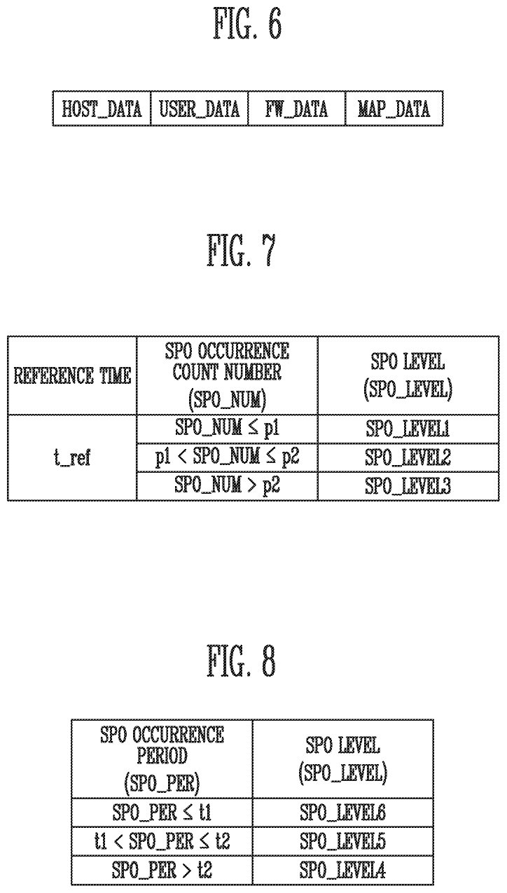

The system data SYS_DATA will be described in more detail with reference to FIG. 6.

The SPO level determination unit 220 may update the SPO level SPO_LEVEL.

In an embodiment, the SPO level determination unit 220 may update the SPO level SPO_LEVEL in response to a request of the host 300. Therefore, if a request for updating the SPO level SPO_LEVEL is received from the host 300, the SPO level determination unit 220 may update the SPO level SPO_LEVEL based on new sensing information SE_INF received from the SPO sensing unit 210. The SPO level determination unit 220 may output the updated SPO level SPO_LEVEL to the system data control unit 230.

In an embodiment, the SPO level determination unit 220 may update the SPO level SPO_LEVEL after a predetermined time has passed. In various embodiments, after a predetermined time has passed, the SPO level determination unit 220 may update the SPO level SPO_LEVEL based on new sensing information SE_INF received from the SPO sensing unit 210. The SPO level determination unit 220 may output the updated SPO level SPO_LEVEL to the system data control unit 230.

The system data control unit 230 may receive the SPO level SPO_LEVEL from the SPO level determination unit 220. The system data control unit 230 may write the system data SYS_DATA in nonvolatile memory cells of the system data storage 240 or the memory device 100 depending on the SPO level SPO_LEVEL. The system data control unit 230 may change the number of times the system data SYS_DATA is stored, depending on the determined SPO level SPO_LEVEL.

In an embodiment, the system data control unit 230 may control the system data SYS_DATA such that, as the SPO level SPO_LEVEL received from the SPO level determination unit 220 is increased, the number of types of system data SYS_DATA to be stored may be increased. In contrast, the system data control unit 230 may control the system data SYS_DATA such that, as the SPO level SPO_LEVEL is decreased, the number of types of system data SYS_DATA stored may be decreased. The system data control unit 230 may control the system data SYS_DATA such that, even if the SPO level SPO_LEVEL is relatively low, mapping-related data among the types of system data SYS. DATA is essentially stored.

Consequently, as the SPO level SPO_LEVEL is decreased, the number of pieces of system data SYS_DATA to be written to the nonvolatile memory cells of the system data storage 240 or the memory device 100 is decreased, so that the efficiency of the storage device may be increased because the number of pieces of data to be written is decreased. The performance of the storage device may be enhanced by adjusting the number of pieces of system data SYS_DATA to be written. In contrast, as the SPO level SPO_LEVEL is increased, the number of pieces of system data SYS_DATA to be written to the nonvolatile memory cells is increased. In this case, the amount of system data SYS_DATA to be recovered by the storage device may be decreased by increasing the number of types of system data SYS_DATA to be written. Thereby, the performance of the storage device may be enhanced.

In an embodiment, as the SPO level SPO_LEVEL is increased, the system data control unit 230 may increase the number of times the system data SYS_DATA is written. In contrast, as the SPO level SPO_LEVEL is decreased, the system data control unit 230 may reduce the number of times the system data SYS_DATA is written.

The system data control unit 230 may store the system data SYS_DATA in the system data storage 240 and/or the memory device 100. The system data SYS_DATA may be stored in nonvolatile memory cells of the system data storage 240 and/or the memory device 100. In various embodiments, the system data control unit 230 may store the system data SYS_DATA determined based on the SPO level SPO_LEVEL. Furthermore, the system data control unit 230 may store the system data SYS_DATA at a write time point determined based on the SPO level SPO_LEVEL.

To store the system data SYS_DATA, the system data control unit 230 may output a system data write command SDW_CMD and the system data SYS_DATA. The system data control unit 230 may output the system data write command SDW_CMD and the system data SYS_DATA to the system data storage 240 and/or the memory device 100. The system data SYS_DATA received from the system data control unit 230 may be stored in nonvolatile memory cells of the systemdata storage 240 and/or the memory device 100.

The system data control unit 230 may write the system data SYS_DATA when system data write conditions are satisfied. In various embodiments, the system data SYS_DATA may be written when a memory block in which data is stored is changed in the memory device 100. Therefore, the system data SYS_DATA may be written when mapping data is updated. Furthermore, the system data SYS_DATA may be written when mapping information (e.g., physical-to-logical (P2L) mapping information) indicating a mapping relationship between physical block addresses (PBAs) and logical block addresses (LBAs) is updated.

Consequently, if the system data write conditions are satisfied, the system data control unit 230 may write, to the nonvolatile memory cells of the system data storage 240 and/or the memory device 100, the system data SYS_DATA determined based on the SPO level SPO_LEVEL at a write time point determined based on the SPO level SPO_LEVEL.

The system data storage 240 may store the system data SYS_DATA. The system data storage 240 may include volatile memory cells or nonvolatile memory cells. If the system data storage 240 includes nonvolatile memory cells, the system data storage 240 may include a read only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), a spin-transfer torque magnetoresistive RAM (S HMRAM), or a phase-change RAM (PCRAM).

In the case where the system data storage 240 includes a nonvolatile memory, the system data control unit 230 may store the system data SYS_DATA in the system data storage 240. Thus, even if the power is turned off, the system data storage 240 may retain the stored system data SYS_DATA. Therefore, if the power is turned on again after the power is turned off, the storage device 50 including the memory controller 200 and the memory device 100 may perform a recovery operation based on the system data SYS_DATA stored in the system data storage 240.

In various embodiments, if an SPO event occurs after the system data storage 240 has stored the system data SYS_DATA, the memory controller 200 may perform a data recovery operation using the system data SYS_DATA that has been stored in the system data storage 240 immediately before the SPO event occurs.

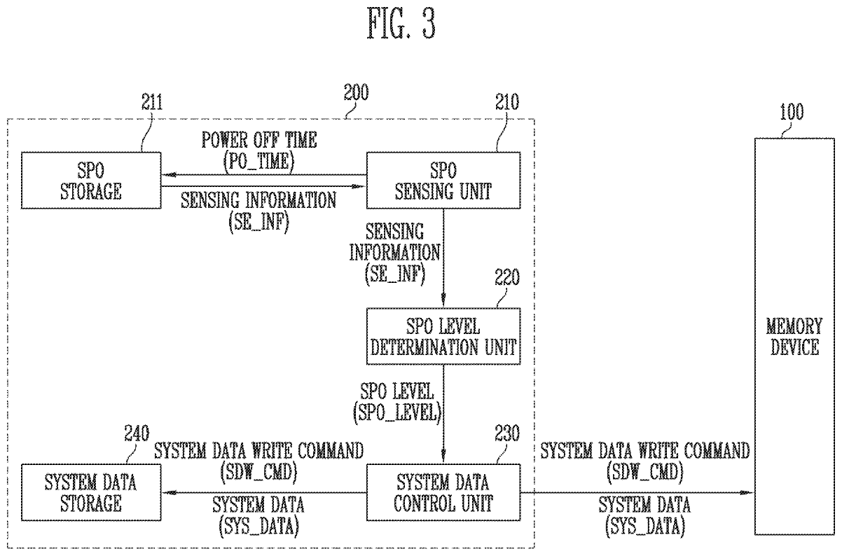

FIG. 3 is a diagram illustrating a memory controller including an SPO storage in accordance with an embodiment of the present disclosure, for example, the memory controller 200 of FIG. 1 including the SPO storage 211.

Referring to FIG. 3, the memory controller 200 may include the SPO sensing unit 210, the SPO storage 211, the SPO level determination unit 220, the system data control unit 230, and the system data storage 240. Although FIG. 3 illustrates the memory controller 200 including the system data storage 240, the system data storage 240 may be implemented outside the memory controller 200.

The memory controller 200 of FIG. 3, other than the SPO storage 211, has the same configuration as that of the memory controller 200 of FIG. 2; therefore, in the description pertaining to the embodiment of FIG. 3, the contents overlapping those of the embodiment of FIG. 2 will be omitted.

The SPO storage 211 may receive a power off time PO_TIME from the SPO sensing unit 210. The power off time PO_TIME may be a point in time at which the power is turned off. The power off time PO_TIME may be stored in the memory device 100 and/or the memory controller 200. In FIG. 3, the power off time PO_TIME is stored in the SPO storage 211 in the memory controller 200.

The SPO storage 211 may store the power off time PO_TIME received from the SPO sensing unit 210. Each time the power off time PO_TIME is received, the SPO storage 211 may store a point in time at which the power off time PO_TIME is received.

The SPO storage 211 may store an SPO occurrence time. The SPO occurrence time may be the time between points in time at which the power off time PO_TIME has been received. In an embodiment, after a first SPO event has occurred, an SPO event may occur again. The SPO event that has occurred after the first SPO event may be a second SPO event. The SPO storage 211 may store the time between the first SPO event and the second SPO event. The time between the first SPO event and the second SPO event may be calculated using the power off time PO_TIME.

The SPO storage 211 may accumulate the SPO occurrence time. The accumulated SPO occurrence time may be stored in the SPO storage 211. In various embodiments, each time an SPO event occurs, an SPO occurrence duration including a preceding SPO occurrence duration may be stored.

The SPO storage 211 may store an SPO occurrence count number. In various embodiments, when the power is turned on again after an SPO event, the SPO storage 211 may count the SPO occurrence count number. When the power is turned on again after an SPO event, the SPO occurrence count number may increase by “1”. The increased SPO occurrence count number may be stored in the SPO storage 211.

The SPO storage 211 may generate sensing information SE_INF based on the power off time PO_TIME. The sensing information SE_INF may include information about the SPO occurrence time and the SPO occurrence count number.

In various embodiments, the SPO occurrence time may be the time between a point in time at which an SPO event has occurred and a point in time at which another SPO event occurs again. The SPO occurrence count number may be the number of times the power off time PO_TIME has been received. Since the SPO occurrence time and the SPO occurrence count number are accumulatively stored, the SPO storage 211 may output, when the power is turned on, the sensing information including information about the accumulated SPO occurrence time and the SPO occurrence count number to the SPO sensing unit 210.

The SPO sensing unit 210 may output, to the SPO level determination unit 220, the sensing information SE_INF received from the SPO storage 211. The SPO level determination unit 220 may determine an SPO level SPO_LEVEL based on the sensing information SE_INF. An operation after the SPO level determination unit 220 receives the sensing information SE_INF and determines the SPO level SPO_LEVEL is the same as that of the embodiment of FIG. 2.

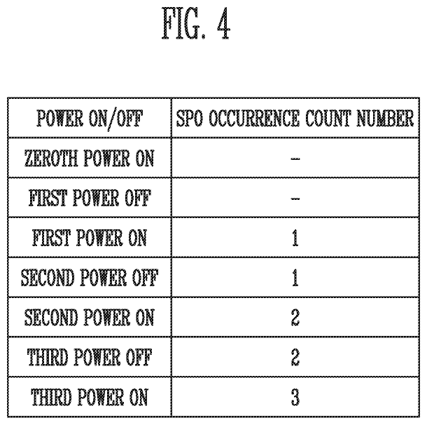

FIG. 4 is a diagram illustrating an operation of updating a sudden power off (SPO) occurrence count number in accordance with an embodiment of the present disclosure.

Referring to FIG. 4, the first column indicates power on or power off, and the second column indicates an SPO occurrence count number recorded in the SPO storage 211 of FIG. 3. In FIG. 4, the power off may be power off resulting from an SPO event.

A zeroth power-on state may indicate that the storage device 50 is initially turned on. In this case, the SPO occurrence count number may not be stored in the SPO storage 211.

A first power-off state may indicate an SPO event which initially occurs. If the SPO event occurs, the SPO storage 211 may store the power off time PO_TIME received from the SPO sensing unit 210. In this case, the SPO occurrence count number may not be stored in the SPO storage 211.

After the first power-off state, the power may be turned on again. This state in which the power is turned on again may be a first power-on state. In the first power-on state, the SPO storage 211 may sense a power-on state and store the SPO occurrence count number. Since the initial SPO event has occurred after the storage device 50 has been initially turned on, the SPO occurrence count number to be stored by the SPO storage 211 may be “1”. After the SPO occurrence count number has been stored, the SPO storage 211 may output, to the SPO sensing unit 210, sensing information SE_INF including information about the stored SPO occurrence count number.

After the first power-on state, an SPO event may occur again. This SPO state may be a second power-off state. In the second power-off state, the SPO storage 211 may store the power off time PO_TIME received from the SPO sensing unit 210. In an embodiment, the SPO occurrence count number stored in the SPO storage 211 may remain “1”.

If the power is turned on again after the second power-off state, the SPO occurrence count number may be increased by “1” and updated to “2”. This state in which the power is turned on again after the second power-off state may be a second power-on state. In the second power-on state, the SPO occurrence count number may be updated to “2”, and the updated SPO occurrence count number may be stored in the SPO storage 211. The SPO storage 211 may output, to the SPO sensing unit 210, the sensing information SE_INF including information about the updated SPO occurrence count number.

After the second power-on state, an SPO event may occur again. This SPO state may be a third power-off state. In the third power-off state, the SPO storage 211 may store the power off time PO_TIME received from the SPO sensing unit 210. In an embodiment, the SPO occurrence count number stored in the SPO storage 211 may remain “2”.

If the power is turned on again after the third power-off state, the SPO occurrence count number may be increased by “1” and updated to “3”. This state in which the power is turned on again after the third power-off state may be a third power-on state. In the third power-on state, the SPO occurrence count number may be updated to “3”, and the updated SPO occurrence count number may be stored in the SPO storage 211. The SPO storage 211 may output, to the SPO sensing unit 210, the sensing information SE_INF including information about the updated SPO occurrence count number.

Although FIG. 4 illustrates a process of updating the SPO occurrence count number from 1 to 3, the SPO occurrence count number which is stored in the SPO storage 211 may be increased.

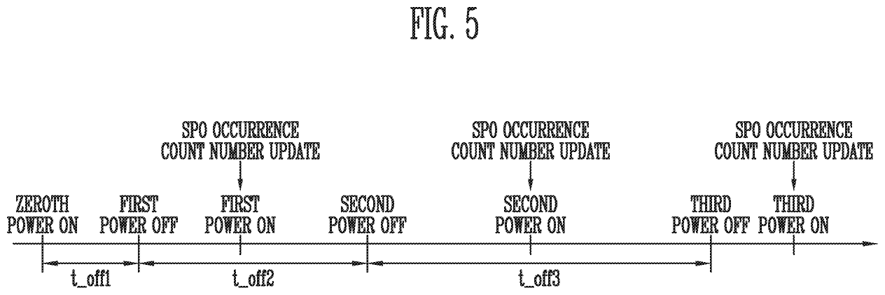

FIG. 5 is a diagram illustrating a method of updating a sudden power off (SPO) occurrence period and the SPO occurrence count number in accordance with an embodiment of the present disclosure.

Referring to FIGS. 4 and 5, FIG. 5 illustrates the state of the storage device 50 from the zeroth power-on state to the third power-on state. That is, FIG. 5 illustrates the state of the storage device 50 in a time sequence from the zeroth power-on state.

The zeroth power-on state may indicate that the storage device 50 is initially turned on. The first power-off state may indicate the initial SPO event. If the SPO event occurs, the SPO storage 211 may store the power off time PO_TIME received from the SPO sensing unit 210. In this case, the SPO occurrence count number may not be stored in the SPO storage 211.

A period between the zeroth power-on time point and the first power-off time point may be a first off time t_off1. The first off time t_off1 may be the time it takes until the initial SPO event occurs. The first off time t_off1 may be a time by which the SPO occurrence period is determined.

After the first power-off state, the power may be turned on again. This state in which the power is turned on again may be the first power-on state. In the first power-on state, the SPO occurrence count number may be updated. Since the power has been turned on after the initial SPO event, the SPO occurrence count number may be updated to “1”. The updated SPO occurrence count number may be stored in the SPO storage 211. Furthermore, in the first power-on state, the SPO storage 211 may store the first off time t_off1. The first off time t_off1 may be a period between the zeroth power-on time point and the first power-off time point.

After the first power-on state,an SPO event may occur again. This SPO state may be the second power-off state. In an embodiment, a period between the first power-off time point and the second power-off time point may be a second off time t_off2. The second off time t_off2 may be the time it takes until, after the SPO event has occurred, another SPO event occurs.

After the second power-off state, the power may be turned on again. This state in which the power is turned on again may be the second power-on state. In the second power-on state, the SPO occurrence count number may be updated. The SPO occurrence count number stored in the SPO storage 211 may be updated from “1” to “2”. The updated SPO occurrence count number may be stored in the SPO storage 211. Furthermore, in the second power-on state, the SPO storage 211 may store the second off time t_off2. The second off time t_ off2 may be a period between the first power-off time point and the second power-off time point.

In the second power-on state, the SPO storage 211 may accumulate and store the SPO occurrence time and the SPO occurrence count number. In various embodiments, the accumulated SPO occurrence time may be a value obtained by adding the first off time t_off1 and the second off time t_off2. Furthermore, the accumulated SPO occurrence count number may be “2” which is an updated value. The SPO storage 211 may output, to the SPO sensing unit 210, sensing information SE_INF including information about the accumulated SPO occurrence time and the accumulated SPO count number.

Based on the accumulated SPO occurrence time and the accumulated SPO count number, the SPO occurrence period and the number of times the SPO event has occurred for a reference time may be determined. In an embodiment, the SPO occurrence period may be a value obtained by dividing the sum of the first off time t_off1 and the second off time t_off2 by the updated SPO occurrence count number. In an embodiment, the number of times the SPO event has occurred for the reference time may be a value determined by comparing the reference time with the sum of the first off time t_off1 and the second off time t_off2.

After the second power-on state, an SPO event may occur again. This SPO state may be a third power-off state. In an embodiment, a period between the second power-off time point and the third power-off time point may be a third off time t_off3. The third off time t_off3 may be the time it takes until, after the SPO event has occurred, another SPO event occurs.

After the third power-off state, the power may be turned on again. This state in which the power is turned on again may be the third power-on state. In the third power-on state, the SPO occurrence count number may be updated. The SPO occurrence count number stored in the SPO storage 211 may be updated from “2” to “3”. The updated SPO occurrence count number may be stored in the SPO storage 211. Furthermore, in the third power-on state, the SPO storage 211 may store a third off time t_off3. The third off time t_off3 may be a period between the second power-off time point and the third power-off time point.

In the third power-on state, the SPO storage 211 may accumulate and store the SPO occurrence time and the SPO occurrence count number. In various embodiments, the accumulated SPO occurrence time may be a value obtained by adding the first off time t_off1, the second off time t_off2, and the third off time t_off3. Furthermore, the accumulated SPO occurrence count number may be “3” which is an updated value. Therefore, the SPO storage 211 may output, to the SPO sensing unit 210, sensing information SE_INF including information about the accumulated SPO occurrence time and the accumulated SPO count number.

Based on the accumulated SPO occurrence time and the accumulated SPO count number, the SPO occurrence period and the number of times the SPO event has occurred for the reference time may be determined. In an embodiment, the SPO occurrence period may be a value obtained by dividing the sum of the first off time t_off1, the second off time t_off2, and the third off time t_off3 by the updated SPO occurrence count number. In an embodiment, the number of times the SPO event has occurred for the reference time may be a value determined by comparing the reference time with the sum of the first off time t_off1, the second off time t_off2, and the third off time t_off3.

FIG. 6 is a diagram illustrating system data SYS_DATA in accordance with an embodiment of the present disclosure. For example, the system data SYS_DATA may be generated by the system data control unit 230 of FIG. 2.

Referring to FIG. 6, the system data SYS_DATA may include at least one of host related data HOST_DATA, user related data USER_DATA, firmware related data FW_DATA, and mapping related data MAP_DATA.

The system data SYS_DATA may be setting data required for the memory controller 200 to control the memory device 100. The system data SYS_DATA may be classified into the host related data HOST_DATA, the user related data USER_DATA, the firmware related data FW_DATA, and the mapping related data MAP_DATA according to contents thereof.

The host related data HOST DATA and the user related data USER_DATA may include booting related information and user related information. The booting related information may include boot loader related information and boot related information. The user related information may include information about a replaced protected memory block (RPMB) and permanent write protect persist within next power on (WP). The boot loader related information may include information required to execute an operating system, load a kernel into a memory, and transfer control of the memory to a host or information required to initialize hardware. The boot related information may include various hardware information, initialization information, and information related to operating system image transmission. The information related to RPMB and WP may include user's main information or confidential information.

The firmware related information FW_DATA may include setting information related to the memory device as firmware system algorithms or hardware register information and FTL related information.

The mapping related information MAP_DATA may include at least one of map indexes (Map Index), map tables (Map T1 to T5), and map translation (Map P2L), and temporary map (Map temp P2L) information. The map indexes may include positions of map related information, and the map tables may include actual map data information of the memory device. The map translation and temporary map information may include information between physical addresses and logical addresses.

The host related data HOST_DATA, the user related data USER_DATA, the firmware related data FW_DATA, and the mapping related data MAP_DATA may be stored in one memory block or distributed and stored in a plurality of memory blocks.

Although the size of the system data SYS_DATA is small, the system data SYS_DATA is very important information required to drive the memory device, and therefore, may be set to store a plurality of copies thereof.

In the case where the erase operation of the memory device is performed on a block basis, when the system data SYS_DATA is updated, system information stored together with the updated system information may be erased. Therefore, in order to prevent this, the system data SYS_DATA may be stored in different memory blocks.

The type of system data SYS_DATA to be stored in the system data storage 240 and/or the memory device 100 may vary depending on the SPO level SPO_LEVEL. In various embodiments, as the SPO level SPO_LEVEL is decreased, the number of times SPO events occur is decreased, so that the number of types of system data SYS_DATA to be stored may be decreased. In contrast, as the SPO level SPO_LEVEL is increased, the number of times SPO events occur is increased, so that the number of types of system data SYS_DATA to be stored may be increased.

The mapping related data MAP_DATA among the types of system data SYS_DATA may be included in system data SYS_DATA to be stored, even though SPO levels SPO_LEVEL thereof are different from each other. Hence, regardless of the SPO level SPO_LEVEL, the mapping related data MAP_DATA may be stored.

FIG. 7 is a diagram illustrating a method of determining a sudden power off (SPO) level in accordance with an embodiment of the present disclosure. For example, the SPO level may be determined by the SPO level determination unit 220.

Referring to FIG. 7, the SPO level determination unit 220 may determine the SPO level SPO_LEVEL based on an SPO occurrence count number SPO_NUM indicating the number of times the SPO event has occurred for a reference time t_ref.

In an embodiment, the reference time t_ref may be previously stored in the SPO level determination unit 220. The reference time t_ref may be a time required to determine the SPO level SPO_LEVEL. The SPO level determination unit 220 may determinate the SPO level SPO_LEVEL while changing the reference time t_ref.

The SPO level determination unit 220 may count an SPO occurrence count number SPO_NUM for the reference time t_ref based on the sensing information received from the SPO sensing unit 210. The SPO level determination unit 220 may determine the SPO level SPO_LEVEL based on the SPO occurrence count number SPO_NUM.

In an embodiment, if the SPO occurrence count number SPO_NUM is p1 or less, the SPO level SPO_LEVEL may be a first SPO level SPO_LEVEL1. If the SPO occurrence count number SPO_NUM is greater than p1 and is p2 or less, the SPO level SPO_LEVEL may be a second SPO level SPO_LEVEL2. If the SPO occurrence count number SPO NUM is greater than p2, the SPO level SPO_LEVEL may be a third SPO level SPO_LEVEL3.

Although FIG. 7 illustrates that a section to which the SPO occurrence count number SPO_NUM may belong is any one of three sections, the number of sections based on which the SPO level SPO_LEVEL is determined may be increased. The sections to which the SPO occurrence count number SPO_NUM may belong may be further subdivided in determining the SPO level SPO_LEVEL.

In an embodiment, the SPO level determination unit 220 may determine one of the first to third SPO levels SPO_LEVEL1 to SPO_LEVEL3 to be the SPO level SPO_LEVEL, based on the sensing information SE_INF received from the SPO sensing unit 210. The SPO level determination unit 220 may output the determined SPO level SPO_LEVEL to the system data control unit 230.

The first SPO level SPO_LEVEL1 may be an SPO level SPO_LEVEL which is determined among the first to third SPO levels SPO_LEVEL1 to SPO_LEVEL3 when the SPO occurrence count number SPO_NUM is smallest. In an embodiment, when the SPO occurrence count number SPO_NUM is p1 or less, the SPO level SPO_LEVEL may be determined to be the first SPO level SPO_LEVEL1. Therefore, since the SPO occurrence count number SPO_NUM indicating the number of times the SPO event has occurred for the reference time t_ref is relatively small, there is no need to frequently write the system data SYS_DATA to the nonvolatile memory cells of the system data storage 240 or the memory device 100. Hence, the system data (SYS_DATA) writing period may be relatively long. The time between write time points at which system data SYS_DATA is written may be increased. Furthermore, since the SPO occurrence count number SPO_NUM is small, the number of types of system data SYS_DATA to be stored may be decreased. However, in this case, the system data SYS_DATA may also include the mapping related data MAP_DATA.

The third SPO level SPO_LEVEL3 may be an SPO level SPO_LEVEL which is determined among the first to third SPO levels SPO_LEVEL1 to SPO_LEVEL3 when the SPO occurrence count number SPO_NUM is largest. In an embodiment, when the SPO occurrence count number SPO_NUM is greater than p2, the SPO level SPO_LEVEL may be determined to be the third SPO level SPO_LEVEL3. Therefore, since the SPO occurrence count number SPO_NUM indicating the number of times the SPO event has occurred for the reference time t_ref is relatively large, there is a need to frequently write the system data SYS_DATA to the nonvolatile memory cells of the system data storage 240 or the memory device 100. Hence, the system data (SYS_DATA) writing period may be relatively short. The time between write time points at which system data SYS_DATA is written may be decreased. Furthermore, since the SPO occurrence count number SPO_NUM is large, the number of types of system data SYS_DATA to be stored may be increased. Therefore, in this case, the system data SYS_DATA may include not only mapping related data MAP_DATA, but also the host related data HOST_DATA, the user related data USER_DATA, and the firmware related data FW_DATA.

The second SPO level SPO_LEVEL2 may be an SPO level SPO_LEVEL which is determined when the SPO occurrence count number SPO_NUM is greater than that of the first SPO level SPO_LEVEL1 and less than that of the third SPO level SPO_LEVEL3. In an embodiment, when the SPO occurrence count number SPO_NUM is greater than p1 and is p2 or less, the SPO level SPO_LEVEL may be determined to be the second SPO level SPO_LEVEL2. Therefore, the SPO occurrence count number SPO_NUM indicating the number of times the SPO event has occurred for the reference time t_ref may be greater than the first SPO level SPO_LEVEL1 and less than the third SPO level SPO_LEVEL3. The period of the second SPO level SPO_LEVEL2 at which the system data SYS_DATA is written to the nonvolatile memory cells may be shorter than the period of the first SPO level SPO_LEVEL1 and longer than the period of the third SPO level SPO_LEVEL3. Furthermore, the number of types of system data SYS_DATA to be stored at the second SPO level SPO_LEVEL2 may be greater than the number of types of system data SYS_DATA to be stored at the first SPO level SPO_LEVEL1, and may be less than the number of types of system data SYS_DATA to be stored at the third SPO level SPO_LEVEL3.

Consequently, in the case where the sensing information SE_INF may include the information about the number of times the SPO event has occurred for the reference time t_ref, as the number of times the SPO event has occurred is increased, the SPO level SPO_LEVEL may be increased. In contrast, as the number of times the SPO event has occurred is decreased, the SPO level SPO_LEVEL may be decreased.

Therefore, as the SPO level SPO_LEVEL is decreased, the number of times the system data SYS_DATA is written is decreased, so that the efficiency of the storage device may be increased. The performance of the storage device may be enhanced by adjusting the number of times the system data SYS_DATA is written. In contrast, as the SPO level SPO_LEVEL is increased, the number of times the system data SYS_DATA is written is increased. In this case, the amount of system data SYS_DATA to be recovered by the storage device may be decreased by frequently writing the system data SYS_DATA. Thereby, the performance of the storage device may be enhanced.

In an embodiment, as the SPO level SPO_LEVEL decreased, the number of pieces of system data SYS_DATA to be written in the nonvolatile memory cells of the system data storage 240 or the memory device 100 is decreased, so that the efficiency of the storage device may be increased because the number of pieces of data to be written is decreased. The performance of the storage device may be enhanced by adjusting the number of pieces of system data SYS_DATA to be written. In contrast, as the SPO level SPO_LEVEL is increased, the number of pieces of system data SYS_DATA to be written to the nonvolatile memory cells of the system data storage 240 or the memory device 100 is increased. In this case, the amount of system data SYS_DATA to be recovered by the storage device may be decreased by increasing the number of types of system data SYS_DATA to be written. Thereby, the performance of the storage device may be enhanced.

If the SPO level SPO_LEVEL is determined to be a comparatively high level, an interval between write time points at which the system data SYS_DATA is written may be decreased. In addition, the number of types of system data SYS_DATA to be written in the nonvolatile memory cells may be increased.

FIG. 8 is a diagram illustrating a method of determining a sudden power off (SPO) level SPO_LEVEL in accordance with an embodiment of the present disclosure. For example, the SPO level SPO_LEVEL may be determined by the SPO level determination unit 220.

Referring to FIG. 8, the SPO level determination unit 220 may determine the SPO level SPO_LEVEL based on an SPO occurrence period SPO_PER.

In an embodiment, the SPO occurrence period SPO_PER may be an average of power-off durations in a reference count number. The reference count number may be predetermined and stored in the SPO level determination unit 220. The reference count number may be the number of times the SPO event has occurred. An SPO section may be a section defined from a power-off time point to a power-on time point.

In various embodiments, the SPO level determination unit 220 may determine the reference count number for determining the SPO occurrence period SPO_PER. The reference count number may be varied. The SPO level determination unit 220 may determine the SPO level SPO_LEVEL by calculating an average of power-off durations in the reference count number.

In an embodiment, if the SPO occurrence period SPO_PER is t1 or less, the SPO level SPO_LEVEL may be a sixth SPO level SPO_LEVEL6. If the SPO occurrence period SPO_PER is greater than t1 and is t2 or less, the SPO level SPO_LEVEL may be a fifth SPO level SPO_LEVEL5. If the SPO occurrence period SPO_PER is greater than t2, the SPO level SPO_LEVEL may be a fourth SPO level SPO_LEVEL4.

Although FIG. 8 illustrates that a section to which the SPO occurrence period SPO_PER may belong is any one of three sections, the number of sections based on which the SPO level SPO LEVEL is determined may be increased. The sections to which the SPO occurrence period SPO_PER may be belong may be further subdivided in determining the SPO level SPO_LEVEL.

In an embodiment, the SPO level determination unit 220 may determine one of the fourth to sixth SPO levels SPO_LEVEL4 to SPO_LEVEL6 to be the SPO level SPO_LEVEL, based on the sensing information SE_INF received from the SPO sensing unit 210. The SPO level determination unit 220 may output the determined SPO level SPO_LEVEL to the system data control unit 230.

The sixth SPO level SPO_LEVEL6 may be an SPO level SPO_LEVEL which is determined among the fourth to sixth SPO levels SPO_LEVEL4 to SPO_LEVEL6 when the SPO occurrence period SPO_PER is shortest. If the SPO occurrence period SPO_PER is relatively short, SPO events may frequently occur. In an embodiment, when the SPO occurrence period SPO_PER is ti or less, the SPO level SPO_LEVEL may be determined to be the sixth SPO level SPO_LEVEL6.

If the SPO level SPO_LEVEL is determined to be the sixth SPO level SPO_LEVEL6, there is a need for the system data control unit 230 to frequently write the system data SYS_DATA to the nonvolatile memory cells because the SPO occurrence period SPO_PER is relatively short. Hence, the system data (SYS_DATA) writing period may be relatively short. The time between write time points at which system data SYS_DATA is written may be decreased. Furthermore, since the SPO occurrence period SPO_PER is short, the number of types of system data SYS_DATA to be stored may be increased. Therefore, in this case, the system data SYS_DATA may include not only mapping related data MAP_DATA, but also the host related data HOST_DATA, the user related data USER_DATA, and the firmware related data FW_DATA.

The fourth SPO level SPO_LEVEL4 may be an SPO level SPO_LEVEL which is determined among the fourth to sixth SPO levels SPO_LEVEL4 to SPO_LEVEL6 when the SPO occurrence period SPO_PER is longest. If the SPO occurrence period SPO_PER is relatively long, the SPO occurrence frequency may be decreased. In an embodiment, when the SPO occurrence period SPO_PER is greater than t2, the SPO level SPO_LEVEL may be determined to be the fourth SPO level SPO_LEVEL4.

If the SPO level SPO LEVEL is determined to be the fourth SPO level SPO_LEVEL4, there is no need for the system data control unit 230 to frequently write the system data SYS_DATA because the SPO occurrence period SPO_PER is relatively long. Hence, the system data (SYS_DATA) writing period may be relatively long. The time between write time points at which system data SYS_DATA is written may be increased. Furthermore, since the SPO occurrence period SPO_PER is long, the number of types of system data SYS_DATA to be stored may be decreased. However, in this case, the system data SYS_DATA may also include the mapping related data MAP_DATA.

The fifth SPO level SPO_LEVEL5 may be an SPO level SPO_LEVEL which is determined when the SPO occurrence period SPO_PER is longer than that of the sixth SPO level SPO_LEVEL6 and shorter than that of the fourth SPO level SPO_LEVEL4. In an embodiment, when the SPO occurrence period SPO_PER is longer than t1 and is shorter than or equal to t2, the SPO level SPO_LEVEL may be determined to be the fifth SPO level SPO_LEVEL5. Therefore, the period at which the system data SYS_DATA is written to the nonvolatile memory cells of the system data storage 240 or the memory device 100 may be shorter than the period of the fourth SPO level SPO_LEVEL4 and longer than the period of the sixth SPO level SPO_LEVEL6. Furthermore, the number of types of system data SYS_DATA to be stored at the fifth SPO level SPO_LEVEL5 in the nonvolatile memory cells may be greater than the number of types of system data SYS_DATA to be stored at the fourth SPO level SPO_LEVEL4, and may be smaller than the number of types of system data SYS_DATA to be stored at the sixth SPO level SPO_LEVEL6.

As the SPO level SPO_LEVEL is increased, the interval between the write time points at which the system data SYS_DATA is written may be decreased, and the number of types of system data SYS_DATA to be written may be increased.

In the case where the SPO level SPO_LEVEL is determined based on the SPO occurrence count number SPO_NUM, the larger the SPO occurrence count number SPO_NUM may be, the higher the SPO level SPO_LEVEL may be. In the case where the SPO level SPO_LEVEL is determined based on the SPO occurrence period SPO_PER, the longer the SPO occurrence period SPO_PER may be, the lower the SPO level SPO_LEVEL may be.

Consequently, when the sensing information SE_INF includes information about the SPO occurrence period SPO_PER, the shorter the SPO occurrence period SPO_PER may be, the higher the SPO level SPO_LEVEL may be. In contrast, the longer the SPO occurrence period SPO_PER may be, the lower the SPO level SPO_LEVEL may be.

Therefore, as the SPO level SPO_LEVEL is decreased, the number of times the system data SYS_DATA is written is decreased, so that the efficiency of the storage device may be increased. The performance of the storage device may be enhanced by adjusting the number of times the system data SYS_DATA is written. In contrast, as the SPO level SPO_LEVEL is increased, the number of times the system data SYS_DATA is written is increased. In this case, the amount of system data SYS_DATA to be recovered by the storage device may be decreased by frequently writing the system data SYS_DATA. Thereby, the performance of the storage device may be enhanced.

In an embodiment, as the SPO level SPO_LEVEL is decreased, the number of pieces of system data SYS_DATA to be written in the nonvolatile memory cells is decreased, so that the efficiency of the storage device may be increased because the number of pieces of data to be written is decreased. The performance of the storage device may be enhanced by adjusting the number of pieces of system data SYS_DATA to be written. In contrast, as the SPO level SPO_LEVEL is increased, the number of pieces of system data SYS_DATA to be written to the nonvolatile memory cells is increased. In this case, the amount of system data SYS_DATA to be recovered by the storage device may be decreased by increasing the number of types of system data SYS_DATA to be written. Thereby, the performance of the storage device may be enhanced.

FIG. 9 is a block diagram illustrating a memory device in accordance with an embodiment of the present disclosure, for example, the memory device 100 of FIG. 1.

Referring to FIG. 9, the memory device 100 may include a lo memory cell array 110, and a peripheral circuit 120. The peripheral circuit 120 may include an address decoder 121, a voltage generator 122, a read and write (read/write) circuit 123, a data input and output (input/output) circuit 124, and a control logic 125.

The memory cell array 110 may include a plurality of memory blocks BLK1 to BLKz. The memory blocks BLK1 to BLKz are connected to the address decoder 121 through row lines RL and connected to the read/write circuit 123 through bit lines BL1 to BLm. Each of the memory blocks BLK1 to BLKz may include a plurality of memory cells. In an embodiment, the plurality of memory cells may be nonvolatile memory cells.

A plurality of memory cells in the memory cell array 110 may be divided into a plurality of blocks according to the purpose of use. System information such as various setting information required to control the memory device 100 may be stored in the plurality of blocks.

Each of the first to z-th memory blocks BLK1 to BLKz includes a plurality of memory cell strings. First to m-th cell strings are respectively coupled to the first to m-th bit lines BL1 to BLm. Each of the first to m-th cell strings includes a drain select transistor, a plurality of memory cells coupled in series to each other, and a source select transistor. The drain select transistor DST is coupled to a drain select line DSL. First to n-th memory cells are respectively coupled to first to n-th word lines. The source select transistor SST is coupled to a source select line SSL. A drain of the drain select transistor DST is coupled to the corresponding bit line. The drain select transistors DST of the first to m-th cell strings are respectively coupled to the first to m-th bit lines BL1 to BLm. A source of the source select transistor SST is coupled to a common source line CSL. In an embodiment, the common source line CSL may be coupled in common to the first to z-th memory blocks BLK1 to BLKz. The drain select line DSL, the first to n-th word lines WL1 to WLn, and the source select line SSL are included in the row lines RL. The drain select line DSL, the first to n-th word lines WL1 to WLn, and the source select line SSL are controlled by the address decoder 121. The common source line CSL is controlled by the control logic 125. The first to m-th bit lines BL1 to BLm are controlled by the read/write circuit 123.

The address decoder 121 is coupled to the memory cell array 110 through the row lines RL. The address decoder 121 may operate under control of the control logic 125. The address decoder 121 receives addresses ADDR through the control logic 125.

In an embodiment, a program operation and a read operation of the memory device 100 may be performed on a page basis.

During the program operation or the read operation, addresses ADDR received by the control logic 125 may include a block address and a row address. The address decoder 121 may decode a block address among the received addresses ADDR. The address decoder 121 may select a corresponding one of the memory blocks BLK1 to BLKz in response to the decoded block address.

The address decoder 121 may decode a row address among the received addresses ADDR. In response to the decoded row address, the address decoder 121 may apply voltages, provided from the voltage generator 122, to the row lines RL and select one word line of the selected memory block.

During an erase operation, the addresses ADDR may include a block address. The address decoder 121 may decode the block address and select one memory block according to the decoded block address. The erase operation may be performed on the entirety or a portion of one memory block.

During a partial erase operation, the addresses ADDR may include block and row addresses. The address decoder 121 may select a corresponding one of the memory blocks BLK1 to BLKz in response to the decoded block address.

The address decoder 121 may decode row addresses among the received addresses ADDR. In response to the decoded row addresses, the address decoder 121 may apply voltages, provided from the voltage generator 122, to the row lines RL and select at least one word line of the selected memory block.

In an embodiment, the address decoder 121 may include a block decoder, a word line decoder, and an address buffer.

The voltage generator 122 may generate a plurality of voltages using an external supply voltage supplied to the memory device 100. The voltage generator 122 may operate under control of the control logic 125.

In an embodiment, the voltage generator 122 may generate an internal supply voltage by regulating the external supply voltage. The internal supply voltage generated from the voltage generator 122 may be used as an operating voltage of the memory device 100.

In an embodiment, the voltage generator 122 may generate a plurality of voltages using the external supply voltage or the internal supply voltage. For example, the voltage generator 122 may include a plurality of pumping capacitors for receiving the internal supply voltage, and generate a plurality of voltages by selectively activating the plurality of pumping capacitors under control of the control logic 125. The generated voltages are applied to selected word lines by the address decoder 121.

During a program operation, the voltage generator 122 may generate a program pulse having a high voltage and a pass pulse lower in voltage level than the program pulse. During a read operation, the voltage generator 122 may generate a read voltage and a pass voltage higher than the read voltage. During an erase operation, the voltage generator 122 may generate an erase voltage.

The read/write circuit 123 may include first to m-th page buffers PB1 to PBm. The first to m-th page buffers PB1 to PBm are coupled to the memory cell array 110 through the first to m-th bit lines BL1 to BLm, respectively. The first to m-th page buffers PB1 to PBm may operate under control of the control logic 125.

The first to m-th page buffers PB1 to PBm may perform data communication with the data input/output circuit 124. During a program operation, the first to m-th page buffers PB1 to PBm may receive data DATA to be stored through the data input/output circuit 124 and data lines DL.

During the program operation, the first to m-th page buffers PB1 to PBm may transmit the data, received through the data input/output circuit 124, to selected memory cells through the bit lines BL1 to BLm when a program pulse is applied to a selected word line. The memory cells in the selected page are programmed based on the transmitted data. A memory cell coupled to a bit line to which a program enable voltage (e.g. a ground voltage) is applied may have an increased threshold voltage. The threshold voltage of a memory cell coupled to a bit line to which a program inhibit voltage (for example, a supply voltage) is applied may be retained. During a program verify operation, the first to m-th page buffers PB1 to PBm may read page data from selected

SS memory cells through the bit lines BL1 to BLm.

During a read operation, the read/write circuit 123 may read data DATA from the memory cells in the selected page through the bit lines BL, and output the read data DATA to the data input/output circuit 124. During an erase operation, the read/write circuit 123 may float the bit lines BL.

In an embodiment, the read/write circuit 123 may include a column select circuit.

The data input/output circuit 124 is coupled to the first to m-th page buffers PB1 to PBm through the data lines DL. The data input/output circuit 124 may operate under control of the control logic 125. During a program operation, the data input/output circuit 124 may receive data to be stored from an external controller (not shown).

The control logic 125 is connected to the address decoder 121, the voltage generator 122, the read/write circuit 123, and the data input/output circuit 124. The control logic 125 may control overall operations of the memory device 100. The control logic 125 may receive a command CMD and addresses ADDR from the external controller. The control logic 125 may control the address decoder 121, the voltage generator 122, the read/write circuit 123, and the data input/output circuit 124 in response to the command CMD.

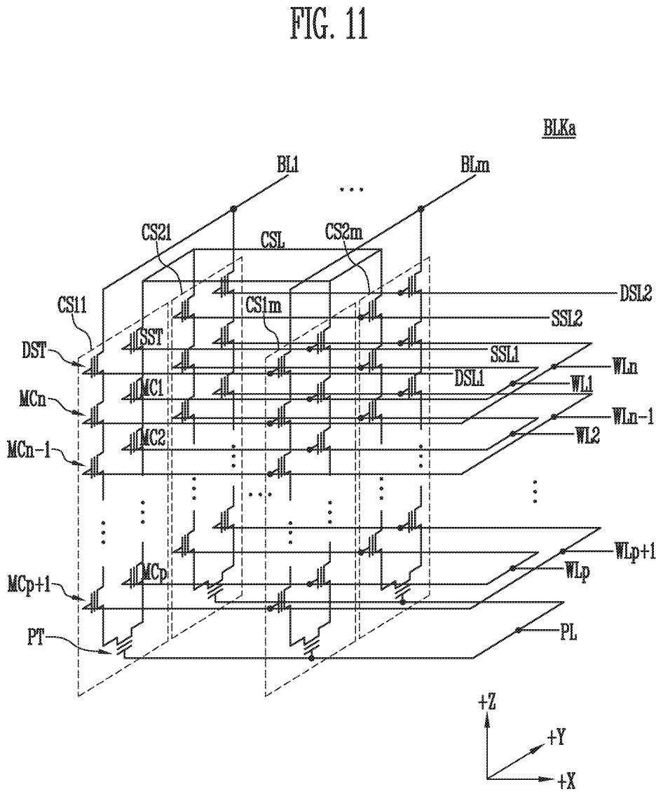

FIG. 10 is a diagram illustrating a memory cell array in accordance with an embodiment of the present disclosure, for example, the memory cell array 110 of FIG. 9.

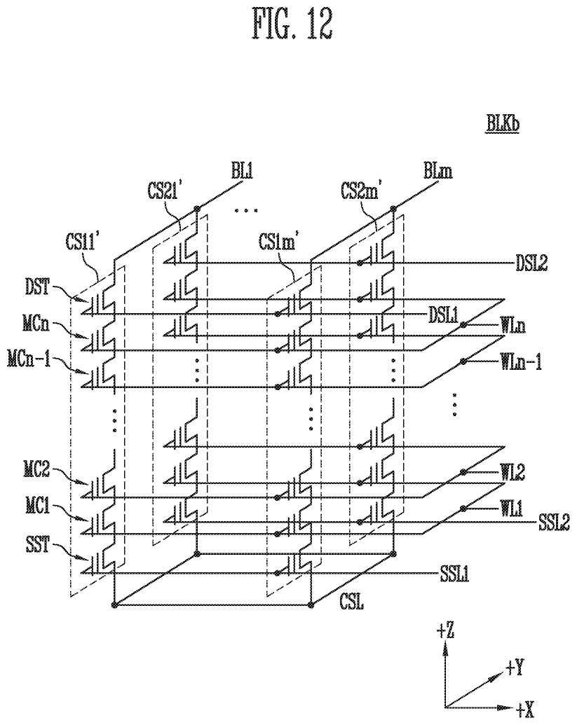

Referring to FIG. 1.0, the memory cell array 110 may include a plurality of memory blocks BLK1 to BLKz. Each memory block may have a three-dimensional structure. Each memory block may include a plurality of memory cells stacked on a substrate. The memory cells are arranged in a +X direction, a +Y direction, and a +Z direction. The structure of each memory block will be described in more detail with reference to FIGS. 11 and 12.

FIG. 11 is a circuit diagram illustrating a memory block in accordance with an embodiment of the present disclosure, for example, a memory block BLKa of a plurality of memory blocks BLK1 to BLKz of FIG. 10.

Referring to FIG. 11, the memory block BLKa may include a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings may be arranged in a row direction (i.e., the +X direction). In FIG. 11, two cell strings are illustrated as being arranged in a column direction (i.e., the +Y direction). However, this illustration is made only for convenience of description, and it will be understood that three or more cell strings may be arranged in the column direction.

Each of the plurality of cell strings CS11 to CS1m and CS21 to CS2m may include at least one source select transistor SST, first to n-th memory cells MC1 to MCn, a pipe transistor PT, and at least one drain select transistor DST.

The select transistors SST and DST and the memory cells MC1 to MCn may have similar structures, respectively. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between the common source line CSL and the memory cells MC1 to MCp.

In an embodiment, source select transistors of cell strings arranged in the same row are coupled to a source select line extending in a row direction, and source select transistors of cell strings arranged in different rows are coupled to different source select lines. In FIG. 11, source select transistors of the cell strings CS11 to CS1m in a first row are coupled to a first source select line SSL1. Source select transistors of the cell strings CS21 to CS2m in a second row are coupled to a second source select line SSL2.

In an embodiment, the source select transistors of the cell strings CS11 to CS1m and CS21 to CS2m may be coupled in common to a single source select line.

The first to n-th memory cells MC1 to MCn in each cell string are coupled between the source select transistor SST and the drain select transistor DST.

The first to n-th memory cells MC1 to MCn may be divided into first to p-th memory cells MC1 to MCp and (p+1)-th to n-th memory cells MCp+1 to MCn. The first to p-th memory cells MC1 to MCp are successively arranged in a direction opposite to the +Z direction and are coupled in series between the source select transistor SST and the pipe transistor PT. The (p+1)-th to n-th memory cells MCp+1 to MCn are successively arranged in the +Z direction and are coupled in series between the pipe transistor PT and the drain select transistor DST. The first to p-th memory cells MC1 to MCp and the (p+1)-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

Respective gates of the pipe transistors PT of the cell strings is are coupled to a pipeline PL.

The drain select transistor DST of each cell string is coupled between the corresponding bit line and the memory cells MCp+1 to MCn. The cell strings arranged in the row direction are coupled to drain select lines extending in the row direction. Drain select transistors of the cell strings CS11 to CS1m in the first row are coupled to a first drain select line DSL1. Drain select transistors of the cell strings CS21 to CS2m in the second row are coupled to a second drain select line DSL2.

Cell strings arranged in the column direction may be coupled to bit lines extending in the column direction. In FIG. 11, cell strings CS11 and CS21 in a first column are coupled to a first bit line BL1. Cell strings CS1m and CS2m in an m-th column are coupled to an m-th bit line BLm.

Memory cells coupled to the same word line in cell strings arranged in the row direction form a single page. For example, memory cells coupled to the first word line WL1, among the cell strings CS11 to CS1m in the first row, form a single page. Memory cells coupled to the first word line WL1, among the cell strings CS21 to CS2m in the second row, form another single page. When any one of the drain select lines DSL1 and DSL2 is selected, corresponding cell strings arranged in the direction of a single row may be selected. When any one of the word lines WL1 to WLn is selected, a corresponding single page may be selected from among the selected cell strings.

In an embodiment, even bit lines and odd bit lines may be provided in lieu of the first to m-th bit lines BL1 to BLm. Even-number-th cell strings of the cell strings CS11 to CS1m or CS21 to CS2m arranged in the row direction may be coupled to respective even bit lines. Odd-number-th cell strings of the cell strings CS11 to CS1m or CS21 to CS2m arranged in the row direction may be coupled to respective odd bit lines.

In an embodiment, at least one of the first to n-th memory cells MC1 to MCn may be used as a dummy memory cell. For example, at least one or more dummy memory cells may be provided to reduce an electric field between the source select transistor SST and the memory cells MC1 to MCp. Alternatively, at least one or more dummy memory cells may be provided to reduce an electric field between the drain select transistor DST and the memory cells MCp+1 to MCn. As the number of dummy memory cells is increased, the reliability in operation of the memory block BLKa may be increased, while the size of the memory block BLKa may be increased. As the number of dummy memory cells is decreased, the size of the memory block BLKa may be decreased, but the reliability in operation of the memory block BLKa may be decreased.

To efficiently control the at least one dummy memory cells, each of the dummy memory cells may have a required threshold voltage. Before or after an erase operation on the memory block BLKa is performed, program operations may be performed on all or some of the dummy memory cells. In the case where an erase operation is performed after a program operation has been performed, the dummy memory cells may have required threshold voltages by controlling voltages to be applied to the dummy word lines coupled to the respective dummy memory cells.

FIG. 12 is a circuit diagram illustrating a memory block in accordance with an embodiment of the present disclosure, for example, a memory block BLKb of a plurality of memory blocks BLK1 to BLKz of FIG. 10.

Referring to FIG. 12, the memory block BLKb may include a plurality of cell strings CS11′ to CS1m′ and CS21′ to CS2m′. Each of the cell strings CS11′ to CS1m′ and CS21′ to CS2m′ extends in the +Z direction. Each of the cell strings CS11′ to CS1m′ and CS21.' to CS2rn′ may include at least one source select transistor SST, first to n-th memory cells MC1 to MCn, and at least one drain select transistor DST which are stacked on a substrate (not shown) provided in a lower portion of the memory block BLK1′.

The source select transistor SST of each cell string is coupled between the common source line CSL and the memory cells MC1 to MCn. The source select transistors of cell strings arranged in the same row are coupled to the same source select line. Source select transistors of the cell strings CS11′ to CS1m′ arranged in a first row may be coupled to a first source select line SSL1. Source select transistors of the cell strings CS21′ to CS2m′ arranged in a second row may be coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string are coupled in series between the source select transistor SST and the drain select transistor DST. Gates of the first to n-th memory cells MC1 to MCn are respectively coupled to first to n-th word lines WL1 to WLn.

The drain select transistor DST of each cell string is coupled between the corresponding bit line and the memory cells MC1 to MCn.

Drain select transistors of cell strings arranged in the row direction may be coupled to drain select lines extending in the row direction. Drain select transistors of the cell strings CS11′ to CS1m′ in the first row are coupled to a first drain select line DSL1. Drain select transistors of the cell strings CS21′ to CS2m′ in the second row may be coupled to a second drain select line DSL2.

Consequently, the memory block BLKb of FIG. 12 may have an equivalent circuit similar to that of the memory block BLKa of FIG. 11 except that a pipe transistor PT is excluded from each cell string.

In an embodiment, even bit lines and odd bit lines may be provided in lieu of the first to m-th bit lines BL1 to BLm. Even-number-th cell strings among the cell strings CS11′ to CS1m′ or CS21′ to CS2m′ arranged in the row direction may be coupled to the respective even bit lines, and odd-number-th cell strings among the cell strings CS11′ to CS1m′ or CS21′ to CS2m′ arranged in the row direction may be coupled to the respective odd bit lines.

In an embodiment, at least one of the first to n-th memory cells MC1 to MCn may be used as a dummy memory cell. For example, at least one or more dummy memory cells may be provided to reduce an electric field between the source select transistor SST and the memory cells MC1 to MCn. Alternatively, at least one or more dummy memory cells may be provided to reduce an electric field between the drain select transistor DST and the memory cells MC1 to MCn. As the number of dummy memory cells is increased, the reliability in operation of the memory block BLKb may be increased, while the size of the memory block BLKb may be increased. As the number of dummy memory cells is decreased, the size of the memory block BLKb may be decreased, but the reliability in operation of the memory block BLKb may be decreased.

To efficiently control the at least one dummy memory cells, each of the dummy memory cells may have a required threshold voltage. Before or after an erase operation on the memory block BLKb is performed, program operations may be performed on all or some of the dummy memory cells. In the case where an erase operation is performed after a program operation has been performed, the dummy memory cells may have required threshold voltages by controlling voltages to be applied to the dummy word lines coupled to the respective dummy memory cells.

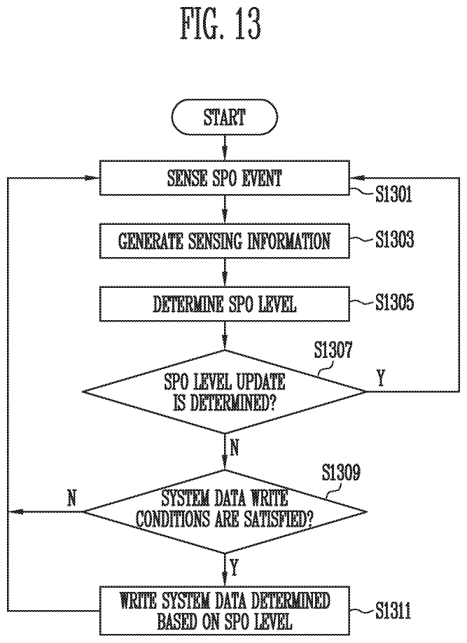

FIG. 13 is a diagram illustrating an operation of a memory controller (e.g., the memory controller 200 of FIG. 2 or 3) in accordance with an embodiment of the present disclosure.

Referring to FIG. 13, at step S1301, the SPO sensing unit 210 may sense an SPO event. The SPO event may be a phenomenon in which the power is suddenly turned off. If the power is suddenly turned off, the SPO sensing unit 210 may control the memory device 100 to store a point in time at which the power is turned off. The point in time at which the power is turned off may be a power off time PO_TIME. The power off time PO_TIME may be stored in the memory device 100.

At step S1303, the SPO sensing unit 210 may generate sensing information SE_INF. In various embodiments, the SPO sensing unit 210 may generate the sensing information SE_INF, based on an SPO duration. The sensing information SE_INF may include at least one of the number of times the SPO event has occurred during a reference time t_ref, and an SPO occurrence period SPO_PER. The SPO occurrence period SPO_PER may be an average of SPO durations.

At step S1305, the SPO level determination unit 220 may determine an SPO level SPO_LEVEL. In various embodiments, the SPO level determination unit 220 may determine the SPO level SPO_LEVEL based on the sensing information SE_INF received from the SPO sensing unit 210. Depending on the SPO level SPO_LEVEL, system data SYS_DATA to be written and a point in time at which the system data SYS_DATA is written may be determined.

The higher the frequency at which SPO events SPO may occur, the higher the SPO level SPO_LEVEL may be. The lower the frequency at which SPO events SPO may occur, the lower the SPO level SPO_LEVEL may be.

At step S1307, the SPO level determination unit 220 may determine whether to update the SPO level SPO_LEVEL. The SPO level determination unit 220 may update the SPO level SPO_LEVEL. In various embodiments, the SPO level determination unit 220 may update the SPO level SPO_LEVEL in response to a request of the host 300 or after a predetermined time has passed. In the case where the SPO determination unit 220 updates the SPO level SPO_LEVEL (S1307, Y), the process proceeds to step S1301 so that the SPO sensing unit 210 senses an SPO event to generate new sensing information SE_INF. In the case where the SPO level determination unit 220 may not update the SPO level SPO_LEVEL (S1307, N), the process proceeds step S1309.

At step S1309, the system data control unit 230 may determine whether the system data write conditions have been satisfied. The system data write conditions may include any one of a change in memory block in which data in the memory device 100 is stored and an update on mapping information (i.e., physical-to-logical (P2L)) indicating a mapping relationship between physical block addresses (PBAs) and logical block addresses (LBAs). The system data write conditions may be varied.

If the system data write conditions are satisfied (S1309, Y), the process proceeds to step S1311. If the system data write conditions are not satisfied (S1309, N), the process proceeds to step S1301. In the case where the system data write conditions are not satisfied, the system data control unit 230 may not write the system data SYS_DATA, and, in order to generate new sensing information SE_INF, the SPO sensing unit is 210 may sense an SPO event.

At step S1311, the system data control unit 230 may store the system data SYS_DATA at a point in time determined based on the SPO level SPO_LEVEL. The system data control unit 230 may write the system data SYS_DATA based on the SPO level SPO_LEVEL received from the SPO level determination unit 220. The system data control unit 230 may write the system data SYS_DATA determined based on the SPO level SPO_LEVEL at the write time point corresponding to the SPO level SPO_LEVEL. After the system data SYS_DATA has been written, the process may proceed to step S1301 again.

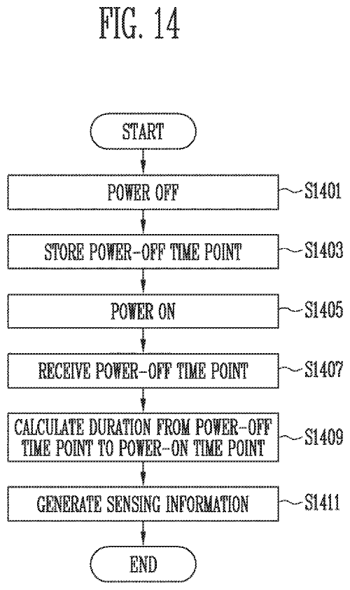

FIG. 14 is a diagram illustrating an operation of a memory controller (e.g., the memory controller 200 of FIG. 2 or 3) in accordance with an embodiment of the present disclosure.

Referring to FIG. 14, at step S1401, the power may be turned off. In various embodiments, the power-off event may be the case where the power is suddenly turned off. If the power is suddenly turned off, the SPO sensing unit 210 may control the memory device 100 to store a point in time at which the power is turned off.

At step S1403, the SPO sensing unit 210 may store the lo power-off time point in the memory device 100. In various embodiments, the power-off time point may be a point in time at which the power is suddenly turned off. The point in time at which the power is suddenly turned off may be a power off time PO_TIME. The power off time PO_TIME may be stored in the memory device 100. The power off time PO_TIME stored in the memory device 100 may be output to generate sensing information SE_INF.

At step S1405, the power may be turned on. In various embodiments, after the SPO event has occurred, the power may be turned on again. In the case where the power is turned on, the storage device 50 may perform a recovery operation using the system data SYS_DATA. The system data SYS_DATA may include at least one of host related data HOST_DATA, user related data USER_DATA, firmware related data FW_DATA, and mapping related data MAP_DATA.

At step S1407, the SPO sensing unit 210 may receive the power-off time point PO_TIME from the memory device 100. In detail, the power-off time point may be the power off time PO_TIME stored in the memory device 100 when the SPO event occurs.

At step S1409, the SPO sensing unit 210 may receive the power off time PO_TIME and calculate a duration from the power off time PO_TIME to a point in time at which the power is turned on again. The SPO sensing unit 210 may calculate, each time an SPO event occurs, a duration from the power off time PO_TIME to a point in time at which the power is turned on again. The duration from the power off time PO_TIME is to the point in time at which the power is turned on again may be accumulatively calculated.

At step S1411, the SPO sensing unit 210 may generate sensing information SE_INF. The SPO sensing unit 210 may sense an SPO event and generate the sensing information SE_INF. In various embodiments, the SPO sensing unit 210 may generate the sensing information SE_INF, based on an SPO duration. The SPO sensing unit 210 may generate the sensing information SE_INF by calculating the duration from the power-off time point to the power-on time point.

The sensing information SE_INF may include information about the number of times the SPO event has occurred for the reference time t_ref. Furthermore, the sensing information SE_INF may include information about an SPO occurrence period SPO_PER. The SPO occurrence period SPO_PER may be an average of SPO durations. The SPO occurrence period SPO_PER may be a value obtained by accumulating the duration from each power-off time point to the corresponding power-on time point and dividing the accumulated duration by the number of times the SPO events have occurred.

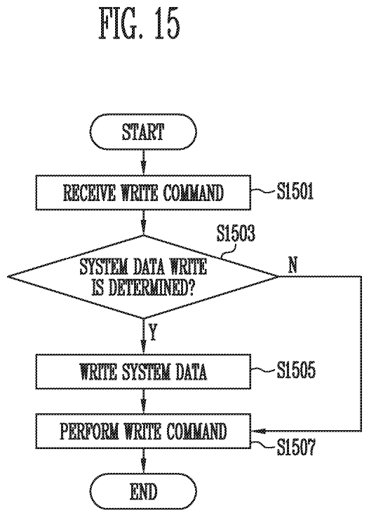

FIG. 15 is a diagram illustrating an operation of a memory device (e.g., the memory device 100 of FIG. 2 or 3) in accordance with an embodiment of the present disclosure.

Referring to FIG. 15, at step S1501, the memory device 100 may receive a write command. When the write command is received from the memory controller 200, the memory device 100 may receive, along with the write command, a physical block address (PBA) on which the write command is performed.

At step S1503, the memory device 100 may determine whether to write system data. In various embodiments, the memory device 100 may receive a system data write command SDW_CMD and system data SYS_DATA from the memory controller 200. If the system data write conditions are satisfied, the memory device 100 may receive the system data write command SDW_CMD and the system data SYS_DATA at a write time point determined based on the SPO level SPO_LEVEL. When the system data write command SDW_CMD and the system data SYS_DATA are received from the memory controller 200, the memory device 100 may determine to write the received system data SYS_DATA.

In the case where the memory device 100 has determined to write the system data SYS_DATA (S1503, Y), the process proceeds to step S1505. In the case where the memory device 100 has determined not to write the system data SYS_DATA (S1503, N), the process proceeds to step S1507.

At step S1505, the memory device 100 may write the system data SYS_DATA received from the system data control unit 230. In various embodiments, the system data SYS_DATA may include mapping information including the PBA received along with the write command. Hence, the point in time at which system data SYS_DATA is written may be delayed as much as possible. Furthermore, since the point in time at which system data SYS_DATA is written may be delayed as much as possible, the system data SYS_DATA which includes a lot of information may be stored in the memory device 100.

At step S1507, the memory device 100 may perform the write command. In various embodiments, the memory device 100 may receive the write command, the address, and write data from the memory controller 200, and perform an operation corresponding to the write command. In the case where it has been determined to write the system data, the memory device 100 may write the system data SYS_DATA and then perform the operation corresponding to the write command. In the case where the memory device 100 does not write the system data SYS_DATA, the memory device 100 may omit the operation of writing the system data SYS_DATA and directly perform the operation corresponding to the write command without.

FIG. 16 is a diagram illustrating an operation of a memory controller (e.g, the memory controller 200 of FIG. 2 or 3) in accordance with an embodiment of the present disclosure.

Referring to FIG. 16, at step S1601, the SPO level determination unit 220 may store a reference time t_ref. The reference time t_ref may be a time required to determine the SPO level SPO_LEVEL. If the SPO level determination unit 220 determines the reference time t_ref, the SPO level determination unit 220 may determine the SPO level SPO_LEVEL based on an SPO occurrence count number SPO_NUM indicating the number of times the SPO event has occurred for the determined reference time t_ref.

At step S1603, the SPO level determination unit 220 may sense the SPO occurrence count number SPO_NUM indicating the number of times the SPO event has occurred for the determined reference time t_ref. In various embodiments, when an SPO event occurs, the SPO level determination unit 220 may receive sensing information SE_INF from the SPO sensing unit 210. The sensing information SE_INF may include information about a time at which the power is turned off by the SPO event SPO, and an SPO occurrence count number SPO_NUM. The SPO level determination unit 220 may determine the SPO occurrence count number SPO_NUM indicating the number of times the SPO event has occurred for the determined reference time t_ref. The SPO occurrence count number SPO_NUM may be determined based on the sensing information SE_INF.

At step S1605, the SPO level determination unit 220 may determine an SPO level SPO_LEVEL. The SPO level SPO_LEVEL may be determined based on the sensing information SE_INF received from the SPO sensing unit 210. The SPO level SPG_LEVEL may be determined based on the SPO occurrence count number SPO_NUM indicating the number of times the SPO event has occurred for the reference time t_ref. In the case where the number of times the SPO event has occurred for the reference time t_ref is relatively small, the SPO level SPO LEVEL may be determined to be a low level. In contrast, if the number of times the SPO event has occurred for the reference time t_ref is relatively large, the SPO level SPO_LEVEL may be determined to be a high level.

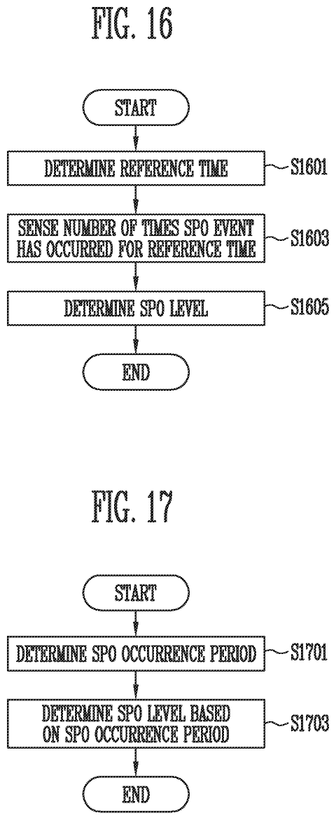

FIG. 17 is a diagram illustrating an operation of a memory controller (e.g., the memory controller 200 of FIG. 2 or 3) in accordance with an embodiment of the present disclosure.

Referring to FIG. 17, at step S1701, the SPO level determination unit 220 may determine an SPO occurrence period SPO_PER. The SPO occurrence period SPO_PER may be determined based on the sensing information SE_INF received from the SPO sensing unit 210. The SPO occurrence period SPO_PER may be an average of power-off durations in a reference count number. The reference count number may be the number of times the SPO event has occurred. The reference count number may be previously stored in the SPO level determination unit 220. An SPO section may be a section defined from a power-off time point to a power-on time point.

If the SPO occurrence period SPO_PER is relatively short, SPO events may frequently occur. If the SPO occurrence period SPO_PER is relatively short, there is a need for the system data control unit 230 to frequently write the system data SYS_DATA. Hence, a period at which the system data SYS_DATA is written to the nonvolatile memory cells of the system data storage 240 or the memory device 100 may be relatively short. The time between write time points at which the system data SYS_DATA is written may be decreased. Furthermore, since the SPO occurrence period SPO_PER is short, the number of types of system data SYS_DATA to be stored may be increased.

In contrast, if the SPO occurrence period SPO_PER is relatively long, the SPO occurrence frequency may be decreased. If the SPO occurrence period SPO_PER is relatively long, there is no need for the system data control unit 230 to frequently write the system data SYS_DATA to the nonvolatile memory cells. Hence, the system data (SYS_DATA) writing period may be relatively long. The time between write time points at which system data SYS_DATA is written may be increased. Furthermore, since the SPO occurrence period SPO_PER is long, the number of types of system data SYS_DATA to be stored may be decreased.

At step S1703, the SPO level determination unit 220 may determine the SPO level SPO_LEVEL based on the SPO occurrence period SPO_PER. In an embodiment, as the SPO occurrence period SPO_PER is decreased, the SPO level SPO_LEVEL may be increased. In contrast, as the SPO occurrence period SPO_PER is increased, the SPO level SPO_LEVEL may be decreased.

FIG. 18 is a diagram illustrating a memory controller in accordance with an embodiment of the present disclosure, for example, the memory controller 1000 of FIG. 1.

The memory controller 1000 is coupled to a host (e.g., the host 300 of FIG. 1) and a memory device (e.g., the memory device 100 of FIG. 1). In response to a request from the host 300, the memory controller 1000 may access the memory device 100. For example, the memory controller 1000 may control a write operation, a read operation, an erase operation, and a background operation of the memory device 100. The memory controller 1000 may provide an interface between the memory device 100 and the host 300. The memory controller 1000 may drive firmware for controlling the memory device 100.

Referring to FIG. 18, the memory controller 1000 may include a processor 1010, a memory buffer 1020, an error correction code (ECC) circuit 1030, a host interface 1040, a buffer control circuit 1050, a memory interface 1060, a bus 1070, and a system data storage 1080.

The bus 1070 may provide a channel between the components of the memory controller 1000.

The processor 1010 may control the overall operation of the memory controller 1000 and perform a logical operation. The processor 1010 may communicate with the host 300 through the host interface 1040, and communicate with the memory device 100 through the memory interface 1060. In addition, the processor 1010 may communicate with the memory buffer 1020 through the buffer control circuit 1050. The processor 1010 may control the operation of the storage device by using the memory buffer 1020 as an operating memory, a cache memory, or a buffer memory.

The processor 1010 may perform the function of a flash translation layer (FTL). The processor 1010 may translate a logical block address (LBA), provided by the host 300, into a physical block address (PBA) through the FTL. The FTL may receive the LBA and translate the LBA into the PBA using a mapping table. An address mapping method using the FTL may be modified in various ways depending on the unit of mapping. Representative address mapping methods may include a page mapping method, a block mapping method, and a hybrid mapping method.

The processor 1010 may randomize data received from the host. For example, the processor 1010 may use a randomizing seed to randomize data received from the host 300. Randomized data may be provided to the memory device 100 as data to be stored, and may be programmed to the memory cell array.

During a read operation, the processor 1010 may derandomize data received from the memory device 100. For example, the processor 1010 may use a derandomizing seed to derandomize data received from the memory device 100. Derandomized data may be output to the host 300.

In an embodiment, the processor 1010 may drive software or firmware to perform the randomizing operation or the derandomizing operation.

In an embodiment, the processor 1010 may perform an operation of determining the type of system data SYS-_DATA to be written in a nonvolatile memory and a write time point of the system data SYS_DATA. The processor 1010 may include the SPO sensing unit 210, the SPO level determination unit 220, and the system data control unit 230 of FIGS. 2 and 3.

In various embodiments, the processor 1010 may sense an SPO event and record a power off time PO_TIME, which is a point in time at which the power is turned off, in the nonvolatile memory included in the memory device and/or the memory controller 1000. Subsequently, the processor 1010 may generate sensing information SE_INF based on an SPO duration. The sensing information SE_INF may include at least one of the number of times the SPO event has occurred during a reference time t_ref, and an SPO occurrence period SPO_PER. The SPO occurrence period SPO_PER may be an average of SPO durations.

The processor 1010 may determine an SPO level SPO_LEVEL based on the sensing information SE_INF. The processor 1010 may determine, based on the SPO level SPO_LEVEL, the type and the write time point of system data SYS_DATA to be written to the memory device and/or the memory controller 1000.

In an embodiment, in the case where the sensing information SE_INF may include the information about the number of times the SPO event has occurred for the reference time t_ref, as the number of times the SPO event has occurred is increased, the SPO level SPO_LEVEL may be increased. In contrast, as the number of times the SPO event has occurred is decreased, the SPO level SPO_LEVEL may be decreased.

In an embodiment, when the sensing information SE_INF includes information about the SPO occurrence period SPO_PER, the shorter the SPO occurrence period SPO_PER, the higher may the SPO level SPO_LEVEL be. In contrast, the longer the SPO occurrence period SPO_PER, the lower may the SPO level SPO_LEVEL be.

If the processor 1010 determines the type of system data SYS_DATA and the write time point of the system data SYS_DATA, the processor 1010 may write the determined type of system data SYS_DATA at the determined write time point. The processor 1010 may write the system data SYS_DATA to the nonvolatile memory included in the memory device and/or the memory controller 1000.

The memory buffer 1020 may be used as an operating memory, a cache memory, or a buffer memory of the processing unit 1010. The memory buffer 1020 may store codes and commands to be executed by the processor 1010. The memory buffer 1020 may store data to be processed by the processor 1010. The memory buffer 1020 may include a static RAM (SRAM) or a dynamic RAM (DRAM).

The ECC circuit 1030 may perform error correction. The ECC circuit 1030 may perform an ECC encoding operation based on data to be written to the memory device 100 through the memory interface 1060. ECC encoded data may be transmitted to the memory device 100 through the memory interface 1060. The ECC circuit 1030 may perform an ECC decoding operation on data received from the memory device 100 through the memory interface 1060. For example, the ECC circuit 1030 may be included in the memory interface 1060 as a component of the memory interface 1060.

The host interface 1040 may communicate with the external host under control of the processor 1010. The host interface 1040 may perform communication using at least one of various communication methods such as a universal serial bus (USB), a serial AT attachment (SATA), a serial attached SCSI (SAS), a high speed intership (HSIC), a small computer system interface (SCSI), a peripheral component interconnection (PCI), a PCI express (PCIe), a nonvolatile memory express (NVMe), a universal flash storage (UFS), a secure digital (SD), multiMedia card (MMC), an embedded MMC (eMMC), a dual in-line memory module (DIMM), a registered DIMM (RDIMM), and a load reduced DIMM (LRDIMM) communication methods.

The buffer control circuit 1050 may control the memory buffer 1020 under control of the processor 1010.

The memory interface 1060 may communicate with the memory device 100 under control of the processor 1010. The memory interface 1060 may communicate a command, an address, and data with the memory device through the channel.

For example, the memory controller 1000 may include neither the memory buffer 1020 nor the buffer control circuit 1050.

For example, the processor 1010 may use codes to control the operation of the memory controller 1000. The processor 1010 may load codes from a nonvolatile memory device (e.g., a read only memory) provided in the memory controller 1000. Alternatively, the processor 1010 may load codes from the memory device through the memory interface 1060.

For example, the bus 1070 of the memory controller 1000 may be divided into a control bus and a data bus. The data bus may transmit data in the memory controller 1000. The control bus may transmit control information such as a command and an address in the memory controller 1000. The data bus and the control bus may be separated from each other and may neither interfere with each other nor affect each other. The data bus may be coupled to the host interface 1040, the buffer control circuit 1050, the ECC circuit 1030, and the memory interface 1060. The control bus may be coupled to the host interface 1040, the processor 1010, the buffer control circuit 1050, the memory buffer 1020, and the memory interface 1060.

The system data storage 1080 may perform the same function as that of the system data storage 240 of FIGS. 2 and 3. The system data storage 1080 may include a nonvolatile memory. The system data storage 1080 may write system data SYS_DATA at a write time point determined by the processor 1010. In an embodiment, the processor 1010 may output a system data write command SDW_CMD and system data SYS_DATA, and store the system data SYS_DATA in the system data storage 1080.

Since the system data storage 1080 includes nonvolatile memory cells, the system data SYS_DATA stored in the system data storage 1080 may be retained even if the power is turned off. Therefore, if the power is turned on again after the power off, the storage device including the memory controller 1000 and the memory device 100 may perform a recovery operation based on the system data SYS_DATA stored in the system data storage 1080.

In various embodiments, if an SPO event occurs after the system data storage 1080 has stored the system data SYS_DATA, the memory controller 1000 may perform a data recovery operation using the system data SYS_DATA that has been stored in the system data storage 1080 immediately before the SPO event occurs.

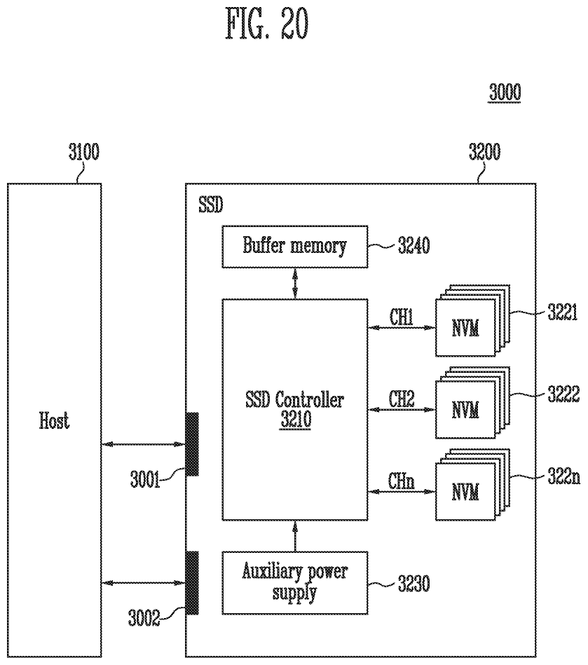

FIG. 19 is a block diagram illustrating a memory card system 2000 including a storage device in accordance with an embodiment of the present disclosure.

Referring to FIG. 19, the memory card system 2000 may include a memory controller 2100, a memory device 2200 and a connector 2300.

The memory controller 2100 is coupled to the memory device 2200. The memory controller 2100 may access the memory device 2200. For example, the memory controller 2100 may control a read operation, a write operation, an erase operation, and a background operation of the memory device 2200. The memory controller 2100 may provide an interface between the memory device 2100 and a host (e.g., the host 300 of FIG. 1). The memory controller 2100 may drive firmware for controlling the memory device 2200. The memory device 2200 may be embodied in the same manner as that of the memory device 100 described with reference to FIG. 9.

In an embodiment, the memory controller 2100 may include components such as a random access memory (RAM), a processing unit, a host interface, a memory interface, and an ECC circuit.

The memory controller 2100 may communicate with an external device through the connector 2300. The memory controller 2100 may communicate with an external device (e.g., a host) based on a specific communication protocol. In an embodiment, the memory controller 2100 may communicate with the external device through at least one of various communication protocols such as universal serial bus (USB), multimedia card (MMC), embedded MMC (eMMC), peripheral component interconnection (PCI), PCI-express (PCI-e or PCIe), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) protocols. In an embodiment, the connector 2300 may be defined by at least one of the above-described various communication protocols.

In an embodiment, the memory device 2200 may be implemented as any of various nonvolatile memory devices, such as an electrically erasable and programmable ROM (EEPROM), a NAND flash memory, a NOR flash memory, a phase-change RAM (PRAM), a resistive RAM (ReRAM), a ferroelectric RAM (FRAM), and a spin-torque magnetic RAM (STT-MRAM).

In an embodiment, the memory controller 2100 and the memory device 2200 may be integrated into a single semiconductor device to form a memory card. For example, the memory controller 2100 and the memory device 2200 may be integrated into a single semiconductor device to form a memory card such as a personal computer memory card international association (PCMCIA), a compact flash card (CF), a smart media card (e.g, SM or SMC), a memory stick, a multimedia card (e.g., MMC, RS-MMC, or MMCmicro), a secure digital (SD) card (e.g., SD, miniSD, microSD, or SDHC), or a universal flash storage (UFS).

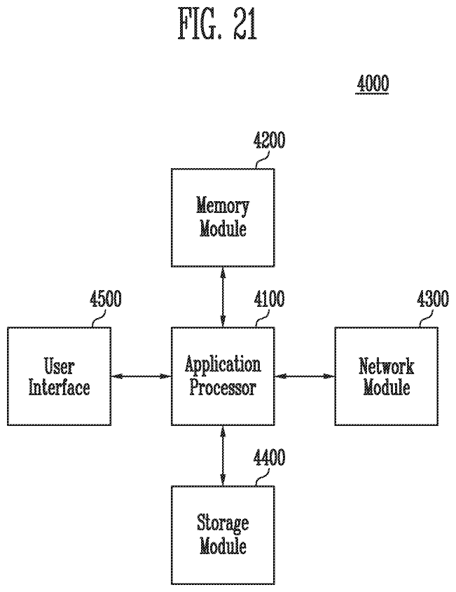

FIG. 20 is a block diagram illustrating a solid state drive (SSD) system 3000 including a storage device in accordance with an embodiment of the present disclosure.

Referring to FIG. 20, the SSD system 3000 may include a host 3100 and an SSD 3200. The SSD 3200 may exchange signals SIG with the host 3100 through a signal connector 3001 and may receive power PWR through a power connector 3002. The SSD 3200 may include an SSD controller 3210, a plurality of flash memories 3221 to 322n, an auxiliary power supply 3230, and a buffer memory 3240.

In an embodiment, the SSD controller 3210 may perform the function of the memory controller 200, described above with reference to FIG. 1.

The SSD controller 3210 may control the plurality of flash memories 3221 to 322n in response to the signals SIG received from the host 3100. In an embodiment, the signals SIG may be signals based on an interface between the host 3100 and the SSD 3200. For example, the signals SIG may be signals defined by at least one of various interfaces such as universal serial bus (USB), multimedia card (MMC), embedded MMC (eMMC), peripheral component interconnection (PCI), PCI-express (PCI-e or PCIe), advanced technology attachment (ATA), serial-ATA (SATA), parallel-ATA (PATA), small computer small interface (SCSI), enhanced small disk interface (ESDI), integrated drive electronics (IDE), Firewire, universal flash storage (UFS), Wi-Fi, Bluetooth, and nonvolatile memory express (NVMe) interfaces.

The auxiliary power supply 3230 may be coupled to the host 3100 through the power connector 3002. The auxiliary power supply 3230 may be supplied with power PWR from the host 3100, and may be charged by the power PWR. The auxiliary power supply 3230 may supply the power of the SSD 3200 when the supply of power from the host 3100 not smoothly performed. In an embodiment, the auxiliary power supply 3230 may be positioned inside the SSD 3200 or positioned outside the SSD 3200. For example, the auxiliary power supply 3230 may be disposed in a main board and may supply auxiliary power to the SSD 3200.

The buffer memory 3240 functions as a buffer memory of the SSD 3200. For example, the buffer memory 3240 may temporarily store data received from the host 3100 or data received from the plurality of flash memories 3221 to 322n or may temporarily store metadata (e.g., a mapping table) of the flash memories 3221 to 322n. The buffer memory 3240 may include volatile memories such as DRAM, SDRAM, DDR SDRAM, LPDDR SDRAM, and GRAM or nonvolatile memories such as FRAM, ReRAM, STT-MRAM, and PRAM.

FIG. 21 is a block diagram illustrating a user system 4000 including a storage device in accordance with an embodiment of the present disclosure.

Referring to FIG. 21, the user system 4000 may include an application processor 4100, a memory module 4200, a network module 4300, a storage module 4400, and a user interface 4500.

The application processor 4100 may run components included in the user system 4000, an operating system (OS) or a user program. In an embodiment, the application processor 4100 may include controllers, interfaces, graphic engines, etc. for controlling the components included in the user system 4000. The application processor 4100 may be provided as a system-on-chip (SoC).

The memory module 4200 may function as a main memory, a working memory, a buffer memory, or a cache memory of the user system 4000. The memory module 4200 may include a volatile RAM such as a DRAM, an SDRAM, a DDR SDRAM, a DDR2 SDRAM, a DDR3 SDRAM, an LPDDR SDARM, and an LPDDR3 SDRAM, or a nonvolatile RAM such as a PRAM, a ReRAM, an MRAM, and an FRAM. In an embodiment, the application processor 4100 and the memory module 4200 may be packaged based on package-on-package (POP) and may then be provided as a single semiconductor package.

The network module 4300 may communicate with external devices. For example, the network module 4300 may support wireless communication, such as code division multiple access (CDMA), global system for mobile communication (GSM), wideband CDMA (WCDMA), CDMA-2000, time division multiple access (TDMA), long term evolution (LTE), VV MAX, WLAN, UWB, Bluetooth, or Wi-Fi communication. In an embodiment, the network module 4300 may be included in the application processor 4100.

The storage module 4400 may store data therein. For example, the storage module 4400 may store data received from the application processor 4100. Alternatively, the storage module 4400 may transmit the data stored in the storage module 4400 to the application processor 4100. In an embodiment, the storage module 4400 may be implemented as a nonvolatile semiconductor memory device, such as a phase-change RAM (PRAM), a magnetic RAM (MRAM), a resistive RAM (RRAM), a NAND flash memory, a NOR flash memory, or a NAND flash memory having a three-dimensional (3D) structure. In an embodiment, the storage module 4400 may be provided as a removable storage medium (i.e., removable drive), such as a memory card or an external drive of the user system 4000.

In an embodiment, the storage module 4400 may include a plurality of nonvolatile memory devices, and each of the plurality of nonvolatile memory devices may be operated in the same manner as that of the memory device 100, described above with reference to FIGS. 9 to 12. The storage module 4400 may be operated in the same manner as that of the storage device 50 described above with reference to FIG. 1.

The user interface 4500 may include interfaces for inputting data or instructions to the application processor 4100 or outputting data to an external device. In an embodiment, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric device. The user interface 4500 may further include user output interfaces such as a liquid crystal display (LCD), an organic light emitting diode (OLED) display device, an active matrix OLED (AMOLED) display device, an LED, a speaker, and a motor.

As described above, various embodiments of the present disclosure may provide a storage device capable of changing a system data write period, and a method of operating the storage device.

Although the embodiments of the present disclosure have been disclosed, those skilled in the art will appreciate that various modifications, additions and substitutions are possible, without departing from the scope and spirit of the present disclosure.

Therefore, the scope of the present disclosure must be defined by the appended claims and equivalents of the claims rather than by the description preceding them.

In the above-discussed embodiments, all steps may be selectively performed or skipped. In addition, the steps in each embodiment may not always be performed in regular order. Furthermore, the embodiments disclosed in the present specification and the drawings aim to help those with ordinary knowledge in this art more clearly understand the present disclosure rather than aiming to limit the bounds of the present disclosure. One of ordinary skill in the art to which the present disclosure belongs will be able to easily understand that various modifications are possible based on the technical scope of the present disclosure.

Embodiments of the present disclosure have been described with reference to the accompanying drawings, and specific terms or words used in the description should be construed in accordance with the spirit of the present disclosure without limiting the subject matter thereof. It should be understood that many variations and modifications of the basic inventive concept described herein will still fall within the spirit and scope of the present disclosure as defined in the appended claims and their equivalents.

What is claimed is:

1. A memory controller configured to control a memory device, the memory controller comprising:
a sudden power off (SPO) sensing unit configured to sense an SPO event and generate sensing information based on the SPO event;
an SPO level determination unit configured to determine an SPO level based on the sensing information;
a system data control unit configured to determine system data to be written based on the SPO level, and a write time point at which the system data is written, and generate a command for storing the system data at the determined write time point; and
a system data storage configured to store the systemdata,
wherein the system data storage includes a nonvolatile memory.

2. The memory controller according to claim 1,
wherein the SPO sensing unit stores, when a power is turned off, a power off time in the memory device, and
wherein the SPO sensing unit receives, when the power is turned on, the power off time from the memory device, and generates the sensing information based on the power off time.

3. The memory controller according to claim 1,
wherein when, the sensing information includes information about the number of times the SPO event has occurred for a reference time,
the number of times the SPO event has occurred is increased, the SPO level is increased.

4. The memory controller according to claim 1,
wherein when, the sensing information includes information about a period at which the SPO event occurs,
the period at which the SPO event occurs is decreased, the SPO level is increased.

5. The memory controller according to claim 1, wherein, when the SPO level is increased, the number of types of system data to be written is increased.

6. The memory controller according to claim 1,
wherein, when the SPO level is increased, a time between write time points at which the system data is written is decreased, and
wherein, when the SPO level is decreased, the time between write time points at which the system data is written is increased.

7. The memory controller according to claim 1, wherein the SPO level determination unit updates the SPO level in response to a request of a host.

8. The memory controller according to claim 1, wherein the SPO level determination unit updates the SPO level after a predetermined reference time has passed.

9. The memory controller according to claim 1,
wherein, when the SPO event occurs after the system data has been stored,
a data recovery operation is performed using the system data that has been stored immediately before the SPO event occurs.

10. The memory controller according to claim 1, wherein the command for storing the system data is generated before a write operation of the memory device is performed.

11. A method of operating a memory controller configured to control a memory device, the method comprising:
sensing a sudden power off (SPO) event and generating sensing information based on the SPO event;
determining an SPO level based on the sensing information;
determining system data to be written and a write time point at which the system data is written, based on the SPO level; and
generating a command for storing the system data at the determined write time point.

12. The method according to claim 11, wherein the generating of the sensing information comprises:
storing, when a power is turned off, a power off time in the memory device, and
receiving, when the power is turned on, the power off time from the memory device, and generating the sensing information based on the power off time.

13. The method according to claim 11,
wherein the generating of the sensing information comprises generating information about a number of times the SPO event has occurred for a reference time, and
wherein the determining of the SPO level comprises determining the SPO level such that, as the number of times the SPO event has occurred is increased, the SPO level is increased.

14. The method according to claim 11,
wherein the generating of the sensing information comprises generating information about a period at which the SPO event occurs, and
wherein the determining of the SPO level comprises determining the SPO level such that, when the period at which the SPO event occurs is decreased, the SPO level is increased.

15. The method according to claim 11, wherein, in the determining of the system data to be written and the write time point,
when the SPO level is increased, the number of types of system data to be written is increased.

16. The method according to claim 11, wherein, in the determining of the system data to be written and the write time point,
when the SPO level is increased, a time between write time points at which the system data is written is decreased, and
when the SPO level is reduced, the time between write time points at which the system data is written is increased.

17. The method according to claim 11, wherein the determining of the SPO level comprises determining an updated SPO level in response to a request of a host.

18. The method according to claim 11, wherein the determining of the SPO level comprises determining an updated SPO level after a predetermined reference time has passed.

19. The method according to claim 11, wherein the generating of the command is performed before a write operation of the memory device is performed.

20. A storage device comprising:
a memory device configured to store data;
a memory controller configured to sense a sudden power off (SPO) event and determine an SPO level, and determine system data to be written based on the SPO level, and a write time point at which the system data is written; and
a system data storage configured to store the system data,
wherein the system data storage includes a nonvolatile memory.
